(19) United States
(12) Patent Application Publication
(10) Pub. No.: US 2025/0275140 A1
(43) Pub. Date: Aug. 28, 2025

(54) SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Hyun Ji KIM, Suwon-si (KR); Seung Yoon KIM, Suwon-si (KR); Jee Hoon HAN, Suwon-si (KR)

(21) Appl. No.: 19/001,652

(22) Filed: Dec. 26, 2024

(30) Foreign Application Priority Data
Feb. 22, 2024 (KR) 10-2024-0026070

(51) Int. Cl. H10B 43/27; G11C 16/04; H01L 25/07; H10B 43/10; H10B 43/40; H10B 80/00

(52) U.S. Cl. CPC H10B 43/27; G11C 16/0483; H01L 25/074; H10B 43/10; H10B 43/40; H10B 80/00; H01L 2225/06506

(57) ABSTRACT

A semiconductor memory device includes a substrate; a stacked structure which includes a plurality of mold insulating films and a plurality of gate electrodes that are alternately stacked on the substrate; and a plurality of gate contacts that penetrate at least a part of the stacked structure, and are electrically connected to the plurality of gate electrodes, wherein the plurality of gate contacts include first to n-th gate contacts (n is a natural number of 3 or more) arranged in sequence along a first direction, the first to (j−1)-th gate contacts are respectively electrically connected to gate electrodes closer to the substrate as they are closer to a j-th gate contact (j is a natural number equal to or greater than 2 and less than n), and the (j+1)-th to n-th gate contacts are respectively electrically connected to gate electrodes that are further from the substrate, as they are further away from the j-th gate contact.

### CROSS-REFERENCE TO RELATED APPLICATION

This application claims priority to Korean Patent Application No. 10-2024-0026070 filed on Feb. 22, 2024, in the Korean Intellectual Property Office, the contents of which in its entirety are herein incorporated by reference.

### BACKGROUND

### 1. Technical Field Disclosure

The present disclosure relates to a semiconductor memory device and an electronic system including the same. More specifically, the present disclosure relates to a semiconductor memory device including memory cells arranged three-dimensionally and an electronic system including the same.

### 2. Description of the Related Art

As semiconductor memory devices capable of storing high-capacity data are required in electronic systems, schemes capable of increasing the data storage capacity of the semiconductor memory devices are being researched. As one scheme for increasing the data storage capacity of the semiconductor memory device, a semiconductor memory device including memory cells arranged three-dimensionally instead of memory cells arranged two-dimensionally has been proposed.

### SUMMARY

Aspects of the present disclosure provide a semiconductor memory device having improved performance and reliability.

Aspects of the present disclosure also provide an electronic system including the semiconductor memory device having improved performance and reliability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, a semiconductor memory device includes a substrate; a stacked structure which includes a plurality of mold insulating films and a plurality of gate electrodes that are alternately stacked on the substrate; and a plurality of gate contacts that penetrate at least a part of the stacked structure, and are electrically connected to the plurality of gate electrodes, wherein the plurality of gate contacts include first to n-th gate contacts (n is a natural number of 3 or more) arranged in sequence along a first direction, the first to (j−1)-th gate contacts are respectively electrically connected to gate electrodes closer to the substrate as they are closer to a j-th gate contact (j is a natural number equal to or greater than 2 and less than n), and the (j+1)-th to n-th gate contacts are respectively electrically connected to gate electrodes that are further from the substrate, as they are further away from the j-th gate contact.

According to another aspect of the present disclosure, a semiconductor memory device includes a substrate which includes a cell array region and an extension region; a stacked structure which includes a plurality of mold insulating films and a plurality of gate electrodes that are alternately stacked on the substrate; a plurality of word line cutting patterns which extend in a first direction and are arranged in a second direction; a plurality of gate contacts each extending in a third direction inside the stacked structure, in the extension region, wherein each of the plurality of gate contacts terminates at a respective one of the plurality of gate electrodes, the plurality of gate contacts include first to n-th gate contacts (n is a natural number of 3 or more) arranged in sequence along the first direction or the second direction, and lengths of each of the first to n-th gate contacts in the third direction increase toward a center of the extension region between the word line cutting patterns adjacent to each other in the second direction.

According to another aspect of the present disclosure, an electronic system includes a main board; a semiconductor memory device which includes a peripheral circuit structure and a memory cell structure stacked in sequence on the main board; and a controller electrically connected to the semiconductor memory device on the main board, wherein the memory cell structure includes a substrate including a cell array region and an extension region, a stacked structure which includes a plurality of mold insulating films and a plurality of gate electrodes alternately stacked on the substrate, a word line cutting pattern which penetrates the stacked structure, and extends in a first direction to separate the plurality of gate electrodes, a channel structure penetrating the stacked structure in the cell array region, and a plurality of gate contacts which penetrate at least a part of the stacked structure and are electrically connected to the plurality of gate electrodes, in the extension region, wherein the plurality of gate contacts include first to n-th gate contacts (n is a natural number of 3 or more) arranged in sequence along the first direction or a second direction intersecting the first direction, the first to (j−1)-th gate contacts are respectively electrically connected to gate electrodes closer to the substrate, as they are closer to a j-th gate contact (j is a natural number equal to or greater than 2 and less than n), and the (j+1)-th to n-th gate contacts are respectively electrically connected to gate electrodes further from the substrate, as they are further away from the j-th gate contact.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a layout diagram for explaining a semiconductor memory device according to some embodiments;

FIG. 2 is an enlarged view of a region R1 of FIG. 1;

FIG. 3 is a cross-sectional view taken along a line A-A′ of FIG. 2;

FIG. 4 is a cross-sectional view taken along a line B-B′ of FIG. 2;

FIG. 5 is an enlarged view of a region R2 of FIG. 3;

FIG. 6 is an enlarged view of a region R3 of FIG. 3;

FIGS. 7 to 18 are intermediate step diagrams for explaining a method for fabricating a semiconductor memory device according to some embodiments;

FIGS. 19 to 23 are intermediate step diagrams for explaining the method for fabricating the semiconductor memory device according to some embodiments;

FIGS. 24 to 26 are intermediate step diagrams for explaining the method for fabricating a semiconductor memory device according to some embodiments;

FIGS. 27 to 29 are intermediate step diagrams for explaining the method for fabricating a semiconductor memory device according to some embodiments;

FIG. 30 is an example block diagram for explaining an electronic system according to some embodiments;

FIG. 31 is an exemplary perspective view for explaining the electronic system according to some embodiments; and

FIG. 32 is a schematic cross-sectional view taken along a line I-I′ of FIG. 31.

### DETAILED DESCRIPTION OF THE EMBODIMENTS

The present disclosure now will be described more fully hereinafter with reference to the accompanying drawings, in which various embodiments are shown. The invention may, however, be embodied in many different forms and should not be construed as limited to the example embodiments set forth herein.

Throughout the specification, when a component is described as “including” a particular element or group of elements, it is to be understood that the component is formed of only the clement or the group of elements, or the element or group of elements may be combined with additional elements to form the component, unless the context indicates otherwise. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Items described in the singular herein may be provided in plural, as can be seen, for example, in the drawings. Thus, the description of a single item that is provided in plural should be understood to be applicable to the remaining plurality of items unless context indicates otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

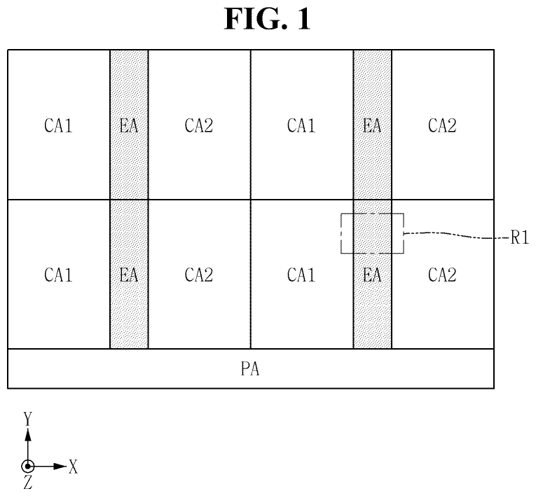

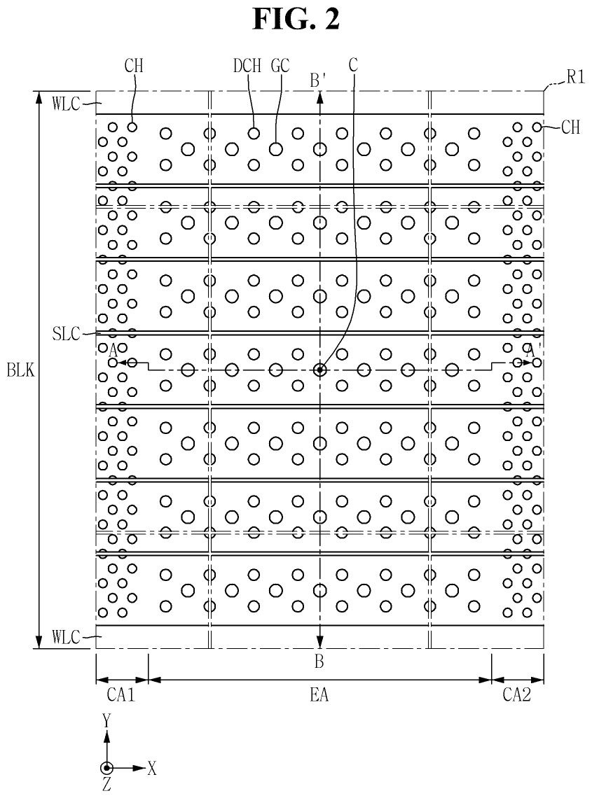

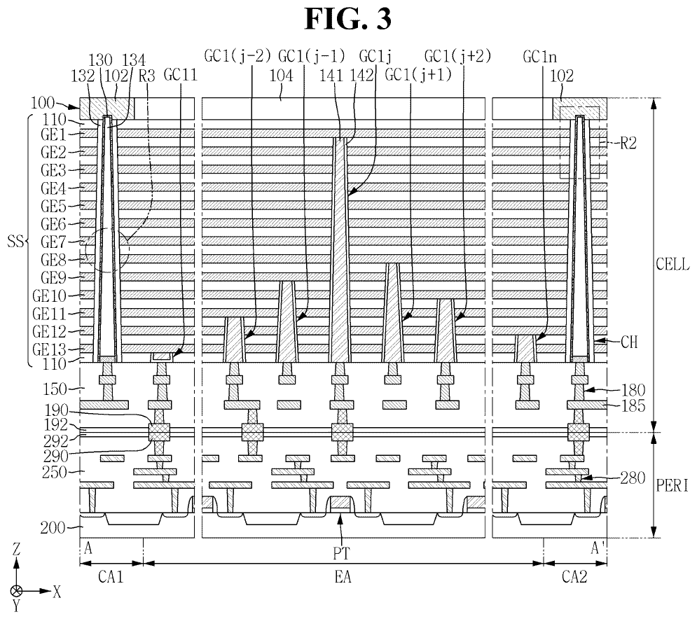

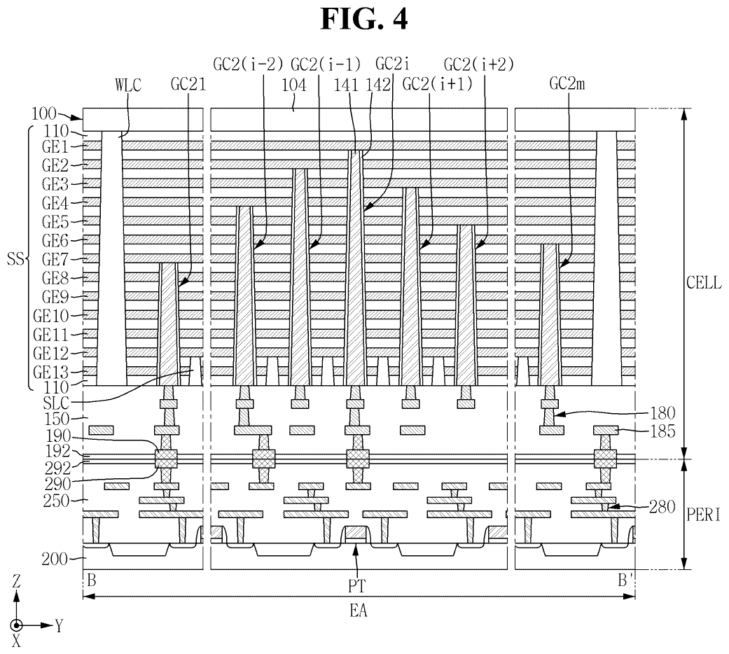

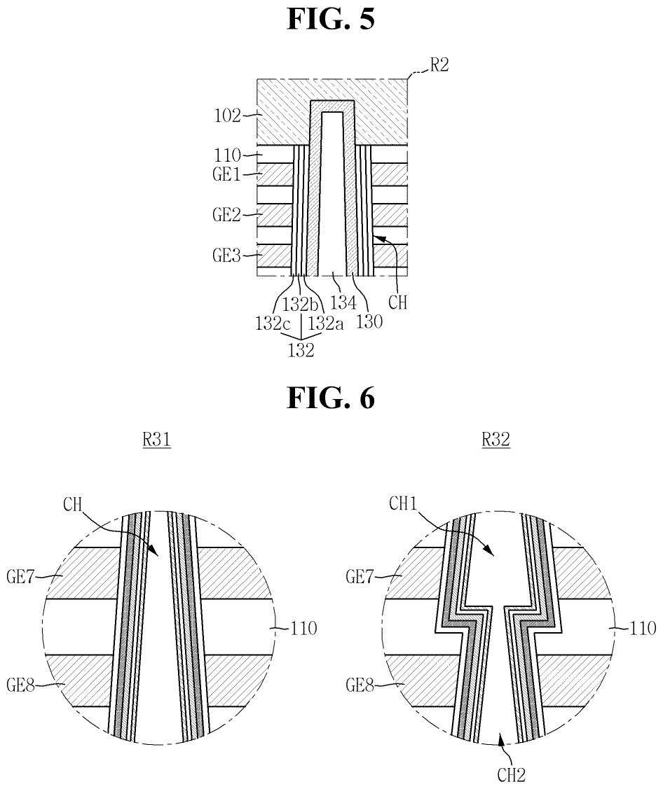

FIG. 1 is a layout diagram for explaining a semiconductor memory device according to some embodiments. FIG. 2 is an enlarged view of a region R1 of FIG. 1. FIG. 3 is a cross-sectional view taken along a line A-A′ of FIG. 2. FIG. 4 is a cross-sectional view taken along a line B-B′ of FIG. 2. FIG. 5 is an enlarged view of a region R2 of FIG. 3. FIG. 6 is an enlarged view of a region R3 of FIG. 3.

Referring to FIGS. 1 to 6, the semiconductor memory device according to some embodiments includes a memory cell structure CELL and a peripheral circuit structure PERI. For example, a semiconductor memory device may be a semiconductor chip, a semiconductor chip stack or chip-on-chip structure, a semiconductor package, or a semiconductor package-on-package device.

The memory cell structure CELL may include cell array regions CA1 and CA2, an extension region EA, and an external region PA.

A memory cell array including a plurality of memory cell blocks BLK may be formed in the cell array regions CA1 and CA2. Each memory cell block BLK may include a plurality of memory cells. For example, a channel structure CH, gate electrodes GE1 to GE13, a conductive line 185, and the like may be disposed in the cell array regions CA1 and CA2.

The extension region EA may be disposed around the cell array regions CA1 and CA2. For example, the extension region EA may be interposed between the first cell array region CA1 and the second cell array region CA2. The first cell array region CA1, the extension region EA, and the second cell array region CA2 may be disposed sequentially along a first direction X. Two cell array regions CA1 and CA2 may share one extension region EA. For example, gate contacts GC11 to GC1n and GC21 to GC2m (n and m are natural numbers of 3 or more) and the like may be disposed in the extension region EA.

The external region PA may be a peripheral region that surrounds the cell array regions CA1 and CA2 and the extension region EA. For example, the external region PA may be adjacent to the cell array regions CA1 and CA2 and/or the extension region EA in the first direction X and/or a second direction Y. For example, a substrate contact that is electrically connected to the first substrate 100, a through-via that electrically connects a first wiring structure 180 and a second wiring structure 280, and the like may be disposed in the external region PA. A plurality of memory cells formed in the cell array regions CA1 and CA2 may be electrically connected to the peripheral circuit elements PT through the through-vias.

The memory cell structure CELL may include a first substrate 100, a stacked structure SS, a channel structure CH, a word line cutting pattern WLC, gate contacts GC11 to GC1n and GC21 to GC2m, and a first wiring structure 180.

The first substrate 100 may be, for example, a semiconductor substrate, such as a silicon substrate, a germanium substrate or a silicon-germanium substrate. Alternatively, the first substrate 100 may be a silicon-on-insulator (SOI) substrate, a germanium-on-insulator (GOI) substrate, or the like.

The first substrate 100 may include a conductive substrate 102 and an insulating substrate 104. For example, the first substrate may include a conductive portion and an insulating portion, which may be at different horizontal regions.

The conductive substrate 102 may include, for example, polysilicon doped with impurities, metal, metal silicide, or the like. The conductive substrate 102 may be formed of a single layer or formed of a plurality of layers. As an example, the conductive substrate 102 may be an n-type semiconductor substrate including n-type impurities (e.g., phosphorus (P), arsenic (As), etc.). As another example, the conductive substrate 102 may include a first conductive film including metal silicide such as tungsten silicide (WSi), and a second conductive film stacked on the first conductive film and including polysilicon doped with impurities. The conductive substrate 102 (e.g., conductive portion) may be provided as and may function at least partly as a common source line of the semiconductor memory device.

The insulating substrate 104 (e.g., insulating portion) may be formed in at least a region of the first substrate 100 including the extension region EA and/or the external region PA. The insulating substrate 104 may form an insulating region within the first substrate 100 that includes the extension region EA and/or the external region PA. The insulating substrate 104 may include, for example, but is not limited to, at least one of silicon oxide, silicon nitride, silicon oxynitride, and silicon carbide.

The stacked structure SS may be formed on the first substrate 100. The stacked structure SS may include a plurality of mold insulating films 110 and a plurality of gate electrodes GE1 to GE13 that are alternately stacked on the first substrate 100. The gate electrodes GE1 to GE13 may be spaced apart from each other by the mold insulating film 110 and stacked in sequence. Each of the gate electrodes GE1 to GE13 may be sequentially stacked on the first substrate 100 and spaced apart from each other. The numbers of the mold insulating film 110 and the gate electrodes GE1 to GE13 are only examples, and are not limited to those shown.

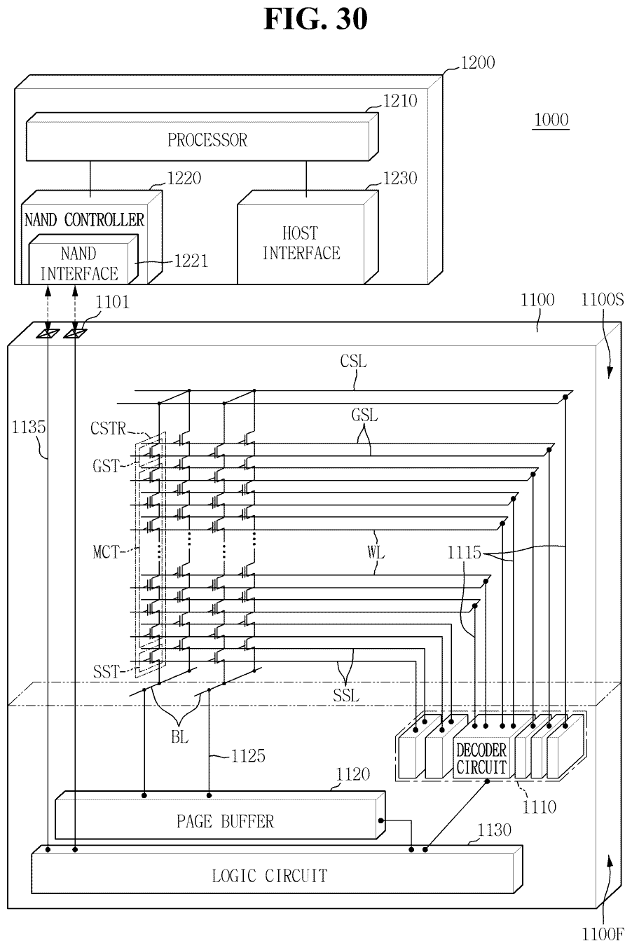

The gate electrodes GE1 to GE13 may include at least one ground selection line (GSL of FIG. 30), a plurality of word lines (WL of FIG. 30), and at least one string selection line (SSL of FIG. 30), which are sequentially stacked on the first substrate 100. For example, the gate electrode GE1 may be provided as a ground selection line, and the gate electrode GE13 may be provided as a string selection line.

The mold insulating film 110 and the gate electrodes GE1 to GE13 may have a layered structure extending along a horizontal plane (for example, an XY plane). In the combined extension region EA and cell array regions CA1 and CA2, the mold insulating film 110 and the gate electrodes GE1 to GE13 extend in the first direction X and the second direction Y. In one embodiment, in the combined extension region EA and the cell array regions CA1 and CA2, each gate electrode GE1 to GE13 may have the same length as the other gate electrodes GE1 to GE13 in the first direction X, and each gate electrode GE1 to GE13 may have the same width as the other gate electrodes GE1 to GE13 in the second direction Y. In the combined extension region EA and cell array regions CA1 and CA2, the gate electrode GE1 closest to the first substrate 100 entirely overlaps the gate electrode GE13 farthest from the first substrate 100, for example, when viewed from a third direction Z. For example, in the extension region EA and the cell array regions CA1 and CA2, the stacked structure SS does not include a stepped structure, and gate electrodes at different vertical levels are congruent (e.g., have the same size, shape, and location) as viewed from a plan view. The third direction Z is a direction from the peripheral circuit structure PERI toward the memory cell structure CELL, and may intersect (for example, be perpendicular to) the first direction X and the second direction Y. The first direction X and the second direction Y may intersect (for example, perpendicular to) each other in a direction parallel to the surface of the first substrate 100 on which the stacked structure SS is disposed. The third direction Z may be described as a vertical direction, and each of the first direction X and second direction Y may be described as a horizontal direction.

Each of the gate electrodes GE1 to GE13 may include, but is not limited to, a conductive material, for example, a metal such as tungsten (W), molybdenium (Mo), ruthenium (Ru), cobalt (Co), or nickel (Ni), or a semiconductor material such as silicon. As an example, in one embodiment, each of the gate electrodes GE1 to GE13 is formed of at least one of tungsten (W), molybdenium (Mo), and/or ruthenium (Ru). In another embodiment, the gate electrodes GE1 to GE13 may each be formed of polysilicon.

The mold insulating film 110 may include, for example, but is not limited to, at least one of silicon oxide, silicon nitride, and/or silicon oxynitride. As an example, each of the mold insulating films 110 may be a silicon oxide film.

The channel structure CH may be disposed inside the cell array regions CA1 and CA2. The channel structure CH may extend in the third direction Z and penetrate the stacked structure SS. The channel structure CH may intersect the gate electrodes GE1 to GE13. For example, the channel structure CH may be a pillar-shaped (for example, cylindrical) structure extending in the third direction Z.

In some embodiments, the plurality of channel structures CH may be arranged in a zigzag form. For example, the plurality of channel structures CH may be arranged alternately in the first direction X and the second direction Y, so that two rows of channel structures CH adjacent to each other in the Y direction include channel structures CH that are not aligned with each other in the Y direction and are offset with respect to each other in the X direction. The number, placement, and the like of the channel structures CH are merely exemplary and are not limited to that shown.

The channel structure CH may include a semiconductor film 130 and a data storage film 132.

The semiconductor film 130 may extend in the third direction Z and intersect the gate electrodes GE1 to GE13. Although the semiconductor film 130 is only shown as being a cup-like shape, this is merely an example. For example, the semiconductor film 130 may have various shapes such as a cylindrical shape, a square barrel shape, and a hollow filler shape. The semiconductor film 130 may be, but is not limited to, a semiconductor material such as, for example, single crystal silicon, polycrystalline silicon (polysilicon), organic semiconductors, and carbon nanostructures. The semiconductor film 130 may include more than one of these materials. In some embodiments, the semiconductor film 130 may be a polysilicon film

The data storage film 132 may be interposed between the semiconductor film 130 and the gate electrodes GE1 to GE13. For example, the data storage film 132 may extend along the outer side surface of the semiconductor film 130. The data storage film 132 may include, for example, but is not limited to, at least one of silicon oxide, silicon nitride, silicon oxynitride, and a high dielectric constant material having a higher dielectric constant than silicon oxide. The high dielectric constant material may be, for example, at least one of aluminum oxide, hafnium oxide, lanthanum oxide, tantalum oxide, titanium oxide, lanthanum hafnium oxide, lanthanum aluminum oxide, dysprosium scandium oxide, and combinations thereof.

In some embodiments, the data storage film 132 may be formed of multiple films. For example, as shown in FIG. 5, the data storage film 132 may include a tunnel insulating film 132a, a charge storage film 132b, and a blocking insulating film 132c, which are sequentially stacked on the outer surface of the semiconductor film 130.

The tunnel insulating film 132a may include, for example, silicon oxide or a high dielectric constant material having a higher dielectric constant than silicon oxide (e.g., aluminum oxide (Al₂O₃), hafnium oxide (HfO₂)). The charge storage film 132b may include,for example, silicon nitride. The blocking insulating film 132c may include, for example, silicon oxide or a high dielectric constant material having a higher dielectric constant than silicon oxide (e.g., aluminum oxide (Al₂O₃), hafnium oxide (HfO₂)).

In some embodiments, the semiconductor film 130 may be electrically connected to the first substrate 100. For example, the semiconductor film 130 may protrude in the third direction Z beyond the stacked structure SS and the data storage film 132. For example, one end (e.g., an upper end in the third direction Z) of the semiconductor film 130 may penetrate a lower part of the data storage film 132, and may be in contact with the first substrate 100.

In some embodiments, the channel structure CH may further include a filling insulating film 134. The filling insulating film 134 may be formed to fill the inside of the cup-shaped semiconductor film 130. The filling insulating film 134 may include an insulating material, for example, but not limited to, silicon oxide.

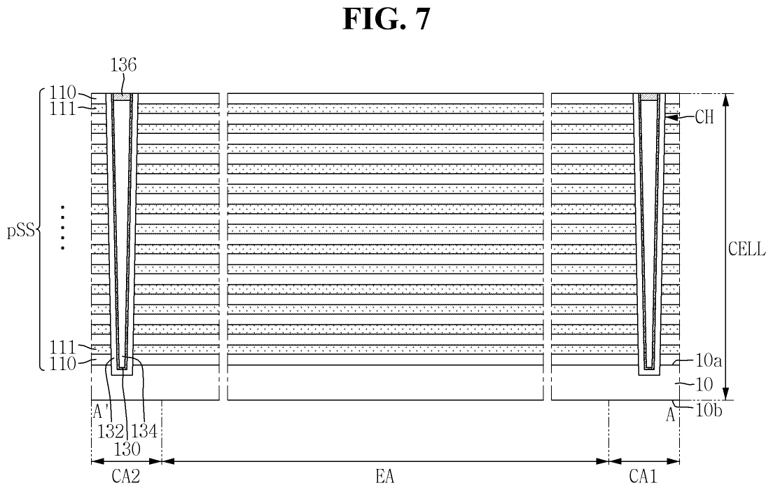

In some embodiments, the channel structure CH may further include a channel pad 136 (see, e.g., FIG. 7). The channel pad 136 may be electrically connected to the other end (for example, an upper end) of the semiconductor film 130. The channel pad 136 may include a conductive material, for example, but not limited to, impurity-doped polysilicon, metal, or metal silicide.

In some embodiments, a dummy channel structure DCH may be formed inside the extension region EA. The dummy channel structure DCH may extend in the third direction Z and penetrate at least a part of the stacked structure SS.

In some embodiments, the channel structure CH penetrating the gate electrodes GE1 to GE13 may not include a bent portion, as shown at R31 of FIG. 6.

In some embodiments, the channel structure CH passing through the gate electrodes GE1 to GE13 may include the bent portion, as shown at R32 of FIG. 6. For example, the channel structure CH may include a first channel structure CH1 and a second channel structure CH2 that are connected to each other. The first channel structure CH1 is formed on the first substrate 100, and the second channel structure CH2 may be formed on the first channel structure CH1. At a boundary between the first channel structure CH1 and the second channel structure CH2, a width of the first channel structure CH1 may be greater than a width of the second channel structure CH2. The channel structure CH may have a bent portion at the boundary between the first channel structure CH1 and the second channel structure CH2. The channel structure CH has the bent portion at the boundary between the first channel structure CH1 and the second channel structure CH2, while the gate contacts GC11 to GC1n and GC21 to GC2m may not have the bent portion. Each of the gate contacts GC11 to GC1n and GC21 to GC2m may include portions connected to each other, and may include a first portion and a second portion on the first portion, and the width of the first portion at the boundary between the first portion and the second portion is not smaller than the width of the second portion at the boundary between the first portion and the second portion. The second portion is further away from the first substrate 100 than the first portion.

The gate electrodes GE7 and GE8 that form the boundary between the first channel structure CH1 and the second channel structure CH2 may be, for example, dummy word lines. Data may not be stored in the memory cells connected to the dummy word line. The voltage level applied to the dummy word line may be different from the voltage level applied to the general word line. The number of gate electrodes GE1 to GE7 that are penetrated by the first channel structure CH1 and the number of gate electrodes GE8 to GE13 that are penetrated by the second channel structure CH2 are merely exemplary, and are not limited thereto.

The dummy channel structure DCH may be formed at the same level as the channel structure CH, or may be formed at a different level from the channel structure CH. As an example, when the dummy channel structure DCH is formed at the same level as the channel structure CH, the dummy channel structure DCH may include the semiconductor film 130, the data storage film 132, the filling insulating film 134 and the channel pad 136 described above. As another example, when the dummy channel structure DCH is formed at a different level from the channel structure CH, the dummy channel structure DCH may be filled with an insulating material and/or a conductive material. The size (e.g., width) of the dummy channel structure DCH may be the same as the size of the channel structure CH, or may be different from the size of the channel structure CH. In some embodiments, the size of the dummy channel structure DCH may be greater than the size of the channel structure CH.

The word line cutting pattern WLC may be formed across the cell array regions CA1 and CA2 and the extension region EA. The word line cutting pattern WLC may extend in the third direction Z and penetrate the stacked structure SS. The word line cutting pattern WLC may extend lengthwise in the first direction X and cut the stacked structure SS. An item, layer, or portion of an item or layer described as extending “lengthwise” in a particular direction has a length in the particular direction and a width perpendicular to that direction, where the length is greater than the width. Further, the plurality of word line cutting patterns WLC may be spaced apart from each other in the second direction Y and extend in parallel in the first direction X. The stacked structure SS may be divided by the word line cutting patterns WLC to form memory cell blocks BLK. For example, two adjacent word line cutting patterns WLC may define one memory cell block BLK between them. Channel structures CH may be disposed inside each memory cell block BLK defined by the word line cutting patterns WLC.

In some embodiments, the word line cutting pattern WLC may include an insulating material, for example, but not limited to, at least one of silicon oxide, silicon nitride, and/or silicon oxynitride. As an example, the word line cutting pattern WLC may include a silicon oxide film.

A string selection line cutting pattern SLC may be disposed between two adjacent word line cutting patterns WLC. The string selection line cutting pattern SLC may cut a gate electrode (e.g., a gate electrode GE13) provided as a string selection line among the gate electrodes GE1 to GE13 of the stacked structure SS. The memory cell block BLK may be divided by the string selection line cutting patterns SLC to form string regions.

The gate electrodes GE1 to GE13 other than the gate electrode (for example, the gate electrode GE13) provided as the string selection line are not separated from each other inside the memory cell block BLK. A cutting pattern like the word line cutting pattern WLC that penetrates the stacked structure SS is not disposed inside the memory cell block BLK. That is, a dummy cutting pattern that separates all the gate electrodes GE1 to GE13 is not disposed inside the memory cell block BLK.

A plurality of gate contacts GC11 to GC1n and GC21 to GC2m are disposed inside the extension region EA. The gate contacts GC11 to GC1n and GC21 to GC2m extend in the third direction Z. Each of the gate contacts GC11 to GC1n and GC21 to GC2m penetrates at least a part of the stacked structure SS, and is electrically connected to a corresponding one of the gate electrodes GE1 to GE13. Each of the gate contacts GC11 to GC1n and GC21 to GC2m may penetrate at least a part of the stacked structure SS and may be in contact with the corresponding one of the gate electrodes GE1 to GE13. The number of gate electrodes GE1 to GE13 through which each of the gate contacts GC11 to GC1n and GC21 to GC2m penetrate is different from each other. In some embodiments, the widths of each of the gate contacts GC11 to GC1n and GC21 to GC2m may decrease in a direction toward the first substrate 100.

The gate contacts GC11 to GC1n and GC21 to GC2m may be arranged along the first direction X and the second direction Y. The gate contacts GC11 to GC1n and GC21 to GC2m may be arranged on each of extension lines extending along the first direction X and extension lines extending along the second direction Y.

The gate contacts arranged on each of the extension lines extending in the first direction X are electrically connected to the gate electrode further from the first substrate 100, as they are closer to the first cell array region CA1 or the second cell array region CA2. The gate contacts arranged on each of the extension lines extending in the first direction X are electrically connected to the gate electrode closer to the first substrate 100, as they are closer to the center of the extension line. The gate contacts arranged on each of the extension lines extending in the first direction X have a longer length penetrating the stacked structure SS, as they are closer to the center of the extension line. The gate contacts arranged on each of the extension lines extending in the first direction X may have a V-shape that is upside down in a XZ plane.

For example, the gate contacts GC11 to GC1n and GC21 to GC2m include first-1 to first-n gate contacts GC11 to GC1n arranged in sequence along the first direction X. A first-1 gate contact GC11 is adjacent to the first cell array region CA1, and a first-n gate contact GC1n is adjacent to the second cell array region CA2.

A first-j gate contact (GC1j, j is a natural number equal to or greater than 2 and less than n) is closest to the center of the extension line extending along the first direction X. The first-j gate contact GC1j has the deepest depth in the third direction Z among the first-1 to first-n gate contacts GC11 to GC1n . The first-j gate contact GC1j is electrically connected to the gate electrode GE1 closest to the first substrate 100 among the gate electrodes GE13, GE11, GE9, GE1, GE8, GE10, and GE12 to which the first-1 to first-n gate contacts GC11 to GC1n are electrically connected. The first-1 to first-(j−1) gate contacts GC11 to GC1 (j−1) are electrically connected to the gate electrodes GE13, GE11 and GE9 to be closer to the first substrate 100 as they are closer to the first-j gate contact GC1j. The first-(j+1) to first-n gate electrodes GE1 (j+1) to GE1n are electrically connected to the gate electrodes GE8, GE10 and GE12 to be closer to the first substrate 100 as they are closer to the first-j gate contact GC1j. The first-1 to first-n gate contacts GC11 to GC1n may have a V-shape that is upside down on the XZ plane.

The lengths of each of the first-1 to first-n gate contacts GC11 to GC1n in the third direction Z may increase, as they are closer to the center C of the extension region EA of the memory cell block BLK. The center C of the extension region EA is a center of the extension region EA of the memory cell block BLK in the first direction X and the second direction Y. The first-j gate contact GC1j may be at the center C of the extension region EA. For example, the number of first-1 to first-(j−1) gate contacts GC11 to GC1 (j−1) may be the same as the number of first-(j+1) to first-n gate contacts GC1 (j+1) to GC1n. The first-j gate contact GC1j may be disposed at the center of the first-1 to first-n gate contacts GC11 to GC1n. In contrast, in some embodiments, the number of first-1 to first-(j−1) gate contacts GC11 to GC1 (j−1) may differ from the number of first-(j+1) to first-n gate contacts GC1 (j+1) to GC1n.

The gate contacts arranged in the second direction Y to be on the extension lines are electrically connected to gate electrodes further from the first substrate 100, as they are closer to the word line cutting pattern WLC. The gate contacts arranged in the second direction Y to be on the extension lines are electrically connected to the gate electrode closer to the first substrate 100, as they are closer to the center of the extension line. The gate contacts arranged in the second direction Y to be on the extension lines have a longer length penetrating the stacked structure SS as they are closer to the center of the extension line. The gate contacts arranged in the second direction Y to be on the extension lines extending in the second direction Y may have a V-shape that is upside down in a YZ plane. Therefore, the gate contacts GC11 to GC1n and GC21 to GC2m may have an inverted pyramid shape.

For example, the gate contacts GC21 to GC2m include second-1 to second-m gate contacts GC21 to GC2m arranged in sequence along the second direction Y. A second-1 gate contact GC21 and a second-m gate contact GC2m are adjacent to different word line cutting patterns WLC, and the different word line cutting patterns WLC are adjacent to each other in the second direction Y.

A second-i gate contact (GC2i, i is a natural number equal to or greater than 2 and less than m) is closest to the center of the extension line extending along the second direction Y. The second-i gate contact GC2i has the deepest depth in the third direction Z among the second-1 to second-m gate contacts GC21 to GC2m. The second-i gate contact GC2i is electrically connected to the gate electrode GE1 closest to the first substrate 100 among the gate electrodes GE7, GE4, GE2, GE1, GE3, GE5 and GE6 to which the second-1 to second-m gate contacts GC21 to GC2m are electrically connected. The second-1 to second-(i−1) gate contacts GC21 to GC2 (i−1) are electrically connected to the gate electrodes GE7, GE4 and GE2 to be closer to the first substrate 100, as they are closer to the second-i gate contact GC2i. The second-(i+1) to second-m gate electrodes GE2 (i+1) to GE2m are electrically connected to the gate electrodes GE3, GE5 and GE6 to be closer to the first substrate 100, as they are closer to the second-i gate contact GC2i. The second-1 to second-m gate contacts GC21 to GC2m may have a V-shape that is upside down on the YZ plane.

The lengths of each of the second-1 to second-(i−1) gate contacts GC21 to GC2 (i−1) in the third direction Z may increase as they are closer to the center C of the extension region EA of the memory cell block BLK. The second-i gate contact GC2i may be at the center C of the extension region EA. The number of second-1 to second-(i−1) gate contacts GC21 to GC2 (i−1) may be identical to the number of second-(i+1) to second-m gate contacts GC2 (i+1) to GC2m. That is, the second-i gate contact GC2i may be disposed at the center of the second-1 to second-m gate contacts GC21 to GC2m. In contrast, in some embodiments, the number of the second-1 to second-(i−1) gate contacts GC21 to GC2 (i−1) may differ from the number of second-(i+1) to second-m gate contacts GC2 (i+1) to GC2m.

Among the plurality of gate contacts GC11 to GC1n and GC21 to GC2m, the gate contact having the longest length in the third direction Z is close to the center C of the extension region EA. Among the plurality of gate contacts GC11 to GC1n and GC21 to GC2m, the gate contact having the shortest length in the third direction Z may be closest to the cell array regions CA1 and CA2 and the word line cutting pattern.

Among the plurality of gate contacts GC11 to GC1n and GC21 to GC2m, the gate contact closest to the center C of the extension region EA is electrically connected to the gate electrode closest to the first substrate 100 among the gate electrodes GE1 to GE13 to which the plurality of gate contacts GC11 to GC1n and GC21 to GC2m are electrically connected. The length that the gate contact closest to the center C of the extension region EA penetrates through the stacked structure SS is the longest among the lengths that each of the gate contacts GC11 to GC1n and GC21 to GC2m penetrate through the stacked structure SS. This gate contact may be the topmost point of the pyramid shape in which the gate contacts GC11 to GC1n and GC21 to GC2m are formed.

For example, the first-j gate contact GC1j may be the second-i gate contact GC2i. The first-j gate contact GC1j may be closest to the center C of the extension region EA. The first-j gate contact GC1j may be disposed at the center C of the extension region EA. The first-j gate contact GC1j may be electrically connected to the gate electrode GE1 closest to the first substrate 100 among the gate contacts GC11 to GC1n and GC21 to GC2m. The first-j gate contact GC1j may have the longest length in the third direction Z among the gate contacts GC11 to GC1n and GC21 to GC2m.

Each of the gate contacts GC11 to GC1n and GC21 to GC2m may include a conductive pattern 141 and an insulating pattern 142. The insulating pattern 142 may be disposed between each of the gate contacts GC11 to GC1n and GC21 to GC2m and the gate electrodes GE1 to GE13 that are not electrically connected to each of the gate contacts GC11 to GC1n and GC21 to GC2m. Each of the gate contacts GC11 to GC1n and GC21 to GC2m and the gate electrodes GE1 to GE13 that are not electrically connected to each of the gate contacts GC11 to GC1n and GC21 to GC2m may be insulated by the insulating pattern 142. The conductive pattern 141 may extend in the third direction Z, and the insulating pattern 142 may wrap the side surface of the conductive pattern 141.

Each of the gate contacts GC11 to GC1n and GC21 to GC2m may contact the corresponding one among the gate electrodes GE1 to GE13, and may terminate at the corresponding one among the gate electrodes GE1 to GE13. For example, one side (for example, an upper side in the third direction Z) of each of the gate contacts GC11 to GC1n and GC21 to GC2m may be in contact with the corresponding one among the gate electrodes GE1 to GE13. For example, the insulating pattern 142 may expose the upper side of the conductive pattern 141 in the third direction Z, and the upper side of the conductive pattern 141 exposed by the insulating pattern 142 may be in contact with the corresponding gate electrodes GE1 to GE13.

The conductive pattern 141 includes a conductive material, and may include at least one of tungsten (W), copper (Cu), aluminum (Al), and alloys thereof. The insulating pattern 142 includes an insulating material, and may include, for example, at least one of silicon oxide, silicon nitride, and silicon oxynitride.

The first wiring structure 180 may be formed on the stacked structure SS. The first wiring structure 180 may be electrically connected to the channel structure CH and/or the gate contacts GC11 to GC1n and GC21 to GC2m. For example, a first inter-wiring insulating film 150 may be formed on the stacked structure SS. The first wiring structure 180 is formed inside the first inter-wiring insulating film 150, and may be connected to the channel structure CH and/or the gate contacts GC11 to GC1n and GC21 to GC2m. The number of layers, placement, and the like of the first wiring structure 180 are merely exemplary, and are not limited to the shown example.

The first wiring structure 180 may include, but is not limited to, at least one of a conductive material, for example, aluminum (Al), copper (Cu), tungsten (W), molybdenium (Mo), cobalt (Co), ruthenium (Ru), and alloys thereof. As an example, the first wiring structure 180 may be copper (Cu) wiring.

In some embodiments, the first wiring structure 180 may include conductive lines 185 disposed inside the cell array regions CA1 and CA2. The conductive line 185 may extend lengthwise in the second direction Y. Further, the conductive lines 185 may be spaced apart from each other in the first direction X and may extend in parallel in the second direction Y.

The conductive line 185 may be electrically connected to the channel structure CH arranged along the second direction Y. For example, the conductive line 185 may be connected to the other end (for example, the upper end) of the semiconductor film 130 through the channel pad 136 of the channel structure CH. The conductive line 185 may be provided as a bit line of the semiconductor device according to some embodiments.

The peripheral circuit structure PERI may include a second substrate 200, a peripheral circuit element PT, and a second wiring structure 280.

The second substrate 200 may include, for example, a semiconductor substrate such as a silicon substrate, a germanium substrate or a silicon-germanium substrate. Alternatively, the second substrate 200 may include a silicon-on-insulator (SOI) substrate, a germanium-on-insulator (GOI) substrate, or the like.

The peripheral circuit element PT may be formed on the second substrate 200. The peripheral circuit element PT may constitute a peripheral circuit that controls the operation of the semiconductor memory device. In the following description, the surface of the second substrate 200 on which the peripheral circuit elements PT are disposed may be referred to as a front side of the second substrate 200. In contrast, the surface of the second substrate 200 opposite to the front side of the second substrate 200 may be referred to as a back side of the second substrate 200.

The peripheral circuit element PT may include, for example, but is not limited to, a transistor. For example, the peripheral circuit element PT may include not only various active elements such as a transistor, but also various passive elements such as a capacitor, a resistor and an inductor.

The second wiring structure 280 may be formed on the peripheral circuit element PT. For example, a second inter-wiring insulating film 250 may be formed on the front side of the second substrate 200. The second wiring structure 280 is formed inside the second inter-wiring insulating film 250 and may be electrically connected to the peripheral circuit element PT. The number of layers, placement, and the like of the shown second wiring structure 280 are merely exemplary, and the present disclosure is not limited thereto.

In some embodiments, the memory cell structure CELL may be stacked on the peripheral circuit structure PERI. For example, the memory cell structure CELL may be stacked on the second inter-wiring insulating film 250. The stacked structure SS may be disposed between the first substrate 100 and the peripheral circuit structure PERI.

The semiconductor memory device according to some embodiments may be a C2C (chip-to-chip) structure. The C2C structure may mean a structure in which an upper chip including a memory cell structure CELL is manufactured on a first wafer, and a lower chip including the peripheral circuit structure PERI is manufactured on a second wafer different from the first wafer, and then, the upper chip and the lower chip are connected to each other by a bonding method such as direct bonding.

As an example, the direct bonding may be a way of electrically connecting a first bonding metal 190 (and/or a first bonding insulating film 192) formed on the uppermost metal layer of the upper chip and a second bonding metal 290 (and/or a second bonding insulating film 292) formed on the uppermost metal layer of the lower chip. For example, when the first bonding metal 190 and the second bonding metal 290 are formed of copper (Cu), the direct bonding may be a Cu-Cu bonding. However, this is exemplary only, and the first bonding metal 190 and the second bonding metal 290 may, of course, be formed of various other metals such as aluminum (Al) or tungsten (W).

As the first bonding metal 190 and the second bonding metal 290 are bonded, the first wiring structure 180 may be connected to the second wiring structure 280. Accordingly, the plurality of memory cells formed in the cell array regions CA1 and CA2 may be electrically connected to the peripheral circuit element PT.

The stacked structure SS of the semiconductor memory device according to some embodiments does not include a stepped structure in the extension region EA. For example, conventional three-dimensional memory including vertical channel structures passing through alternating gate electrode and insulating layers may include stepped structures in a connection region outside of a cell array region, and gate electrode contacts connect to each step at a different vertical height. However, according to the above embodiment, since the gate contacts GC11 to GC1n and GC21 to GC2m may be formed without forming the gate electrodes GE1 to GE13 in a stepped shape, the cutting pattern like a word line cutting pattern WLC penetrating the stacked structure SS is not disposed inside the memory cell block BLK. Therefore, because a space for the extension region EA in which the gate contacts GC11 to GC1n and GC21 to GC2m are disposed may be secured due to the region from which the cutting pattern is removed, the length of the extension region EA in the first direction X may decrease. Furthermore, because the two cell array regions CA1 and CA2 may share one extension region EA, the length of the extension region EA in the second direction Y may decrease.

Further, the gate contacts GC11 to GC1n and GC21 to GC2m may be formed without a separate process for forming the gate electrodes GE1 to GE13 in a stepped shape, thereby improving and/or enhancing the productivity of the semiconductor memory device.

When gate contacts having a relatively long length penetrating the stacked structure SS are deflected to one side, leaning of the stacked structure SS may occur due to the difference in the volume of the gate contacts. For example, the gate electrodes arranged on each extension line extending in the first direction X may have a shorter length in the third direction Z as they go away from the first cell array region CA1. In this case, the gate electrodes having a relatively long length in the third direction Z may be disposed adjacent to the first cell array region CA1. Therefore, the difference between the volume of the gate electrodes adjacent to the first cell array region CA1 and the volume of the gate electrodes far from the first cell array region CA1 increases, and the stacked structure SS may lean.

In the semiconductor memory device according to some embodiments, the gate contacts GC11 to GC1n and GC21 to GC2m have an inverted pyramid shape. Gate contacts having a relatively long length penetrating the stacked structure SS may be disposed at the central portion of the extension region EA. Therefore, leaning of the stacked structure SS may be prevented.

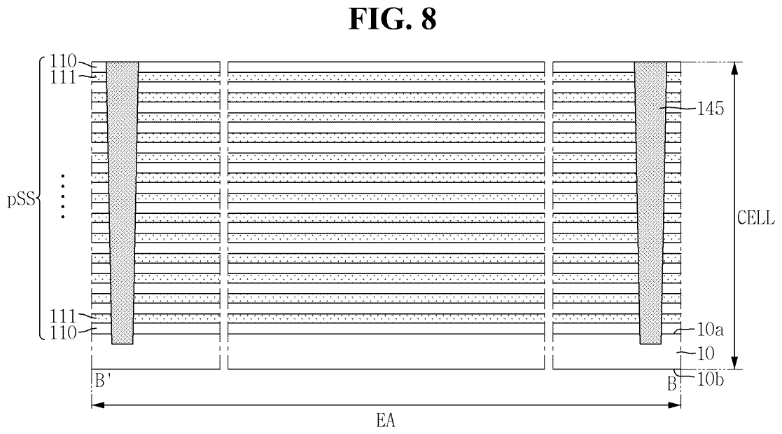

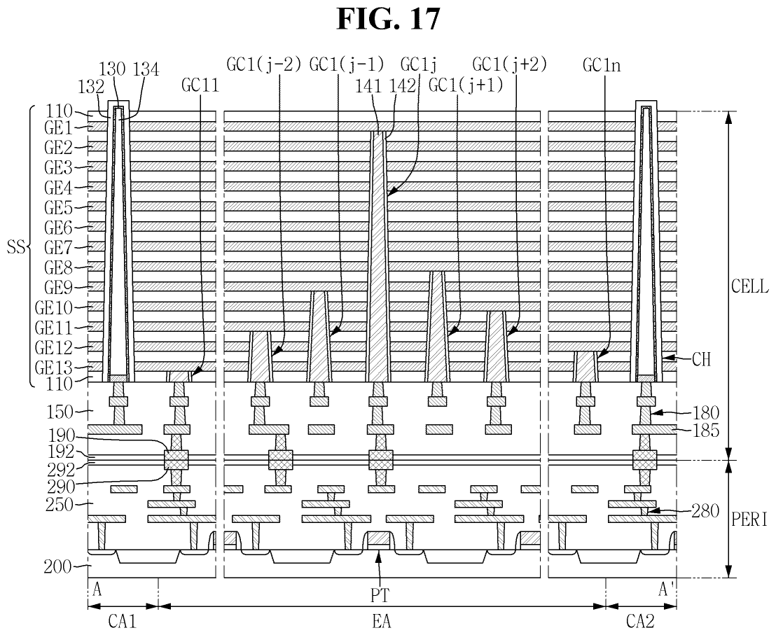

FIGS. 7 to 18 are intermediate step diagrams for explaining a method for fabricating a semiconductor memory device according to some embodiments. For convenience of explanation, repeated parts of contents described above using FIGS. 1 to 6 will be briefly explained or omitted. For reference, FIGS. 7 and 17 are cross-sectional views taken along a line A-A′ of FIG. 2, and FIGS. 8 to 16 and 18 are cross-sectional views taken along a line B-B′ of FIG. 2. In FIGS. 7 to 18, illustration of the string selection line cutting pattern in FIGS. 2 to 4 is omitted for convenience.

Referring to FIGS. 7 and 8, a preliminary stack pSS, a channel structure CH, and a preliminary word line cutting pattern 145 are formed on the base substrate 10.

The base substrate 10 may be, for example, a semiconductor substrate such as a silicon substrate, a germanium substrate or a silicon-germanium substrate. Alternatively, the base substrate 10 may be a silicon-on-insulator (SOI) substrate, a germanium-on-insulator (GOI) substrate, or the like. The base substrate 10 includes a first side 10a and a second side 10b that are opposite to each other.

The preliminary stack pSS is formed on the first side 10a of the base substrate 10. The preliminary stack pSS may include a plurality of mold insulating films 110 and a plurality of mold sacrificial films 111 that are alternately stacked on the first side 10a of the base substrate 10. The mold sacrificial films 111 may include a material having an etching selectivity with respect to the mold insulating film 110. As an example, each mold insulating film 110 may be a silicon oxide film, and each mold sacrificial film 111 may be a silicon nitride film.

The channel structure CH may penetrate through the preliminary stack pSS. A part of the channel structure CH may extend into the base substrate 10. The lower side of the channel structure CH may be disposed between the first side 10a and the second side 10b of the base substrate 10, on the basis of the direction from the second side 10b to the first side 10a of the base substrate 10.

A preliminary word line cutting pattern 145, may penetrate through the preliminary stack pSS. A part of the preliminary word line cutting pattern 145 may extend into the base substrate 10. The lower side of the preliminary word line cutting pattern 145 may be disposed between the first side 10a and the second side 10b of the base substrate 10, on the basis of the direction from the second side 10b to the first side 10a of the base substrate 10. The preliminary word line cutting pattern 145 may include a material having an etching selectivity with respect to the mold insulating films 110 and the mold sacrificial films 111. As an example, the preliminary word line cutting pattern 145 may be polysilicon (poly-Si).

The channel hole in which the channel structure CH is formed may be formed simultaneously with the word line cutting hole in which the preliminary word line cutting pattern 145 is formed, or may be formed separately from the word line cutting hole.

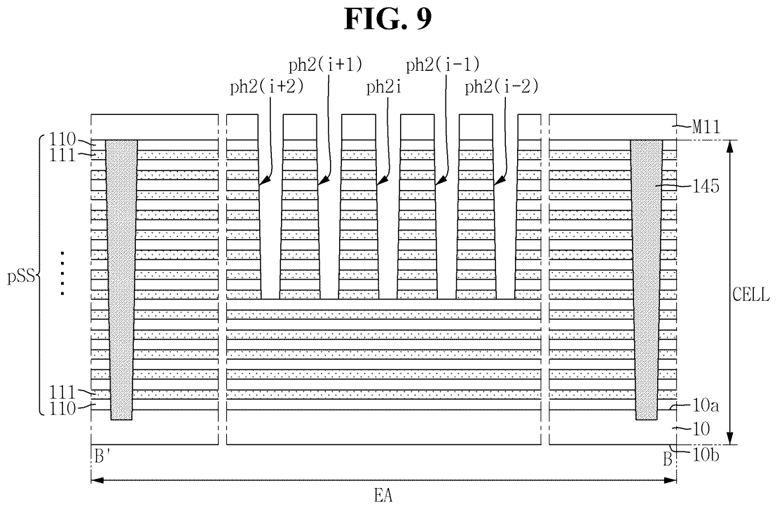

Referring to FIGS. 9 to 14, preliminary contact holes ph21 to ph2m are formed in the preliminary stack pSS. In some embodiments, a process in which the number of layers of the mold insulating film 110 and the mold sacrificial film 111 etched using a mask pattern is large may be performed first.

Referring to FIG. 9, a mask pattern M11 is formed on the preliminary stack pSS, and the preliminary stack pSS is patterned using the mask pattern M11.

For example, preliminary contact holes ph2 (i−2) to ph2 (i+2) may be formed by etching the mold insulating film 110 of eight layers and the mold sacrificial film 111 of eight layers exposed by the mask pattern M11. The number of layers of the mold insulating film 110 and the mold sacrificial film 111 to be etched is not limited thereto. The mask pattern M11 is removed.

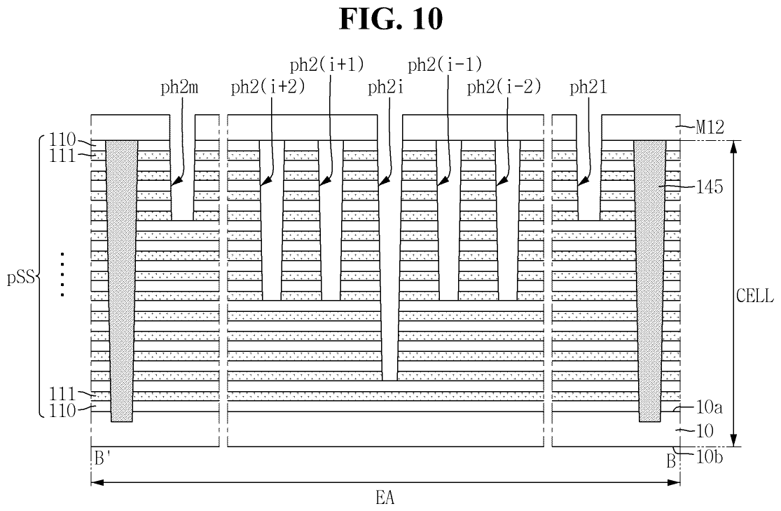

Referring to FIG. 10, a mask pattern M12 is formed on the preliminary stack pSS, and the preliminary stack pSS is patterned using the mask pattern M12. The number of layers of the mold insulating film 110 and the mold sacrificial film 111 that are etched using the mask pattern M12 is smaller than the number of layers of the mold insulating film 110 and the mold sacrificial film 111 that are etched using the mask pattern (M11 of FIG. 9).

For example, the mask pattern M12 may cover the entrances of the preliminary contact holes ph2 (i−2), ph2 (i−1), ph2 (i+1), and ph2 (i+2). Preliminary contact holes ph21, ph2i, and ph2m may be formed by etching the mold insulating film 110 of four layers and the mold sacrificial film 111 of four layers exposed by the mask pattern M12. The number of layers of the mold insulating film 110 and the mold sacrificial film 111 to be etched is not limited thereto. The mask pattern M12 is removed.

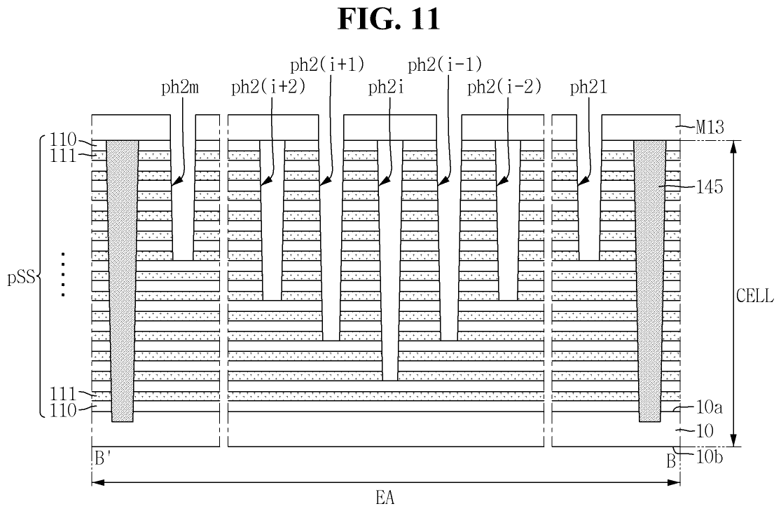

Referring to FIG. 11, a mask pattern M13 is formed on the preliminary stack pSS, and the preliminary stack pSS is patterned using the mask pattern M13. The number of layers of the mold insulating films 110 and the mold sacrificial films 111 that are etched using the mask pattern M13 is smaller than the number of layers of the mold insulating films 110 and the mold sacrificial films 111 that are etched using the mask pattern (M12 of FIG. 10).

For example, the mask pattern M13 may cover the entrances of the preliminary contact holes ph2 (i−2), ph2i, and ph2 (i+2). By etching the mold insulating film 110 of two layers and the mold sacrificial film 111 of two layers exposed by the mask pattern M13, preliminary contact holes ph21, ph2 (i−1), ph2 (i+1), and ph2m may be formed. The number of layers of the mold insulating films 110 and the mold sacrificial films 111 to be etched is not limited thereto. The mask pattern M13 is removed.

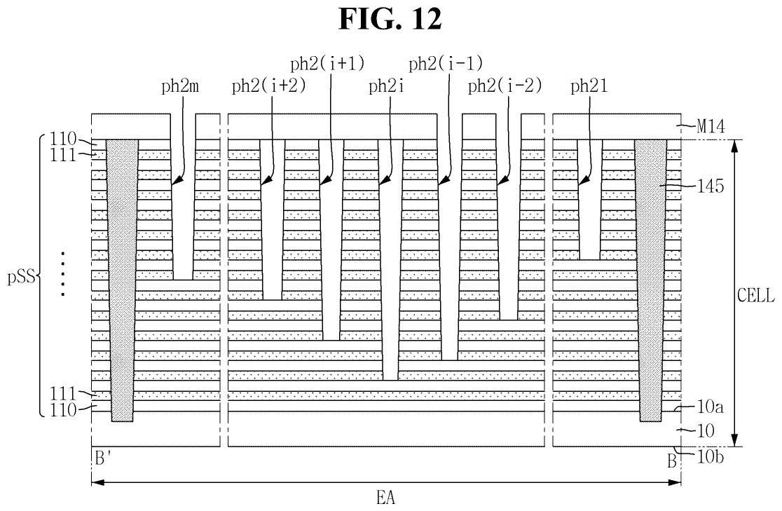

Referring to FIG. 12, a mask pattern M14 is formed on the preliminary stack pSS, and the preliminary stack pSS is patterned using the mask pattern M14. The number of layers of the mold insulating film 110 and the mold sacrificial film 111 that are etched using the mask pattern M14 is smaller than the number of layers of the mold insulating film 110 and the mold sacrificial film 111 that are etched using the mask pattern (M13 of FIG. 11).

For example, the mask pattern M14 may cover the entrances of the preliminary contact holes ph21, ph2i, ph2 (i+1), and ph2 (i+2). Preliminary contact holes ph2 (i−2), ph2 (i−1), and ph2m may be formed, by etching the mold insulating film 110 of one layer and the mold sacrificial film 111 of one layer exposed by the mask pattern M14. The number of layers of the mold insulating film 110 and the mold sacrificial film 111 to be etched is not limited thereto. The mask pattern M14 is removed.

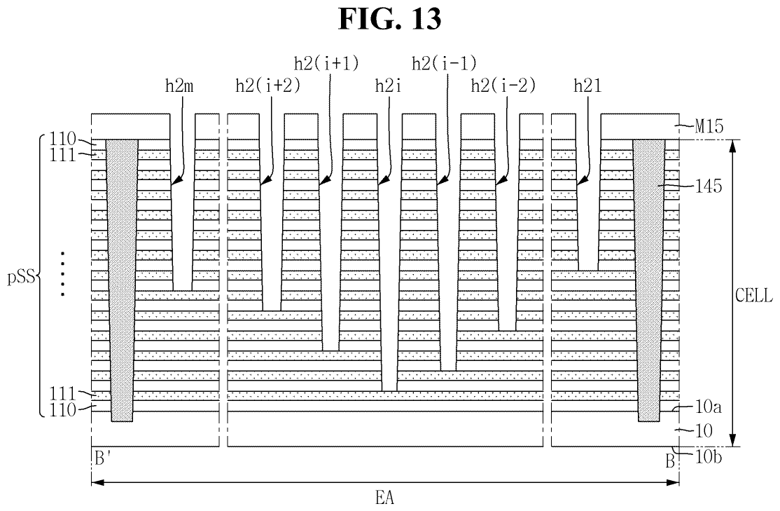

Referring to FIG. 13, a mask pattern M15 is formed on the preliminary stack pSS, and the preliminary stack pSS is patterned using the mask pattern M15. The number of layers of the mold insulating film 110 and the mold sacrificial film 111 that are etched using the mask pattern M15 is smaller than the number of layers of the mold insulating film 110 and the mold sacrificial film 111 that are etched using the mask pattern (M14 of FIG. 12).

For example, the mask pattern M15 may expose the preliminary contact holes (ph21 to ph2m of FIG. 12). The mold insulating film 110 of one layer exposed by the mask pattern M15 may be etched to form contact holes h21 to h2m. The number of layers of the mold insulating film 110 and the mold sacrificial film 111 to be etched is not limited thereto. The mask pattern M15 is removed. Accordingly, the gate contact holes h21 to h2m are formed.

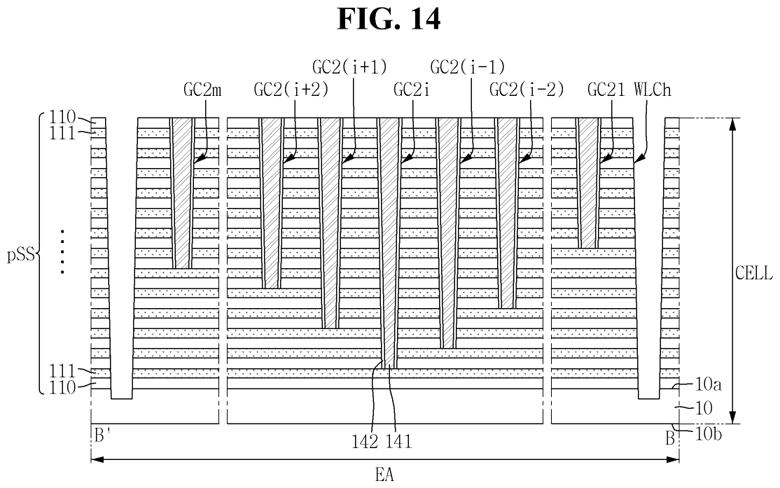

Referring to FIG. 14, a word line cutting hole WLCh and gate contacts GC21 to GC2m are formed.

The preliminary word line cutting pattern (145 of FIG. 13) may be removed. As a result, the word line cutting hole WLCh is formed.

Gate contacts GC21 to GC2m that fill each of the gate contact holes (h21 to h2m of FIG. 13) may be formed. The insulating pattern 142 may include a material having an etching selectivity with respect to the mold insulating film 110 and the mold sacrificial film 111.

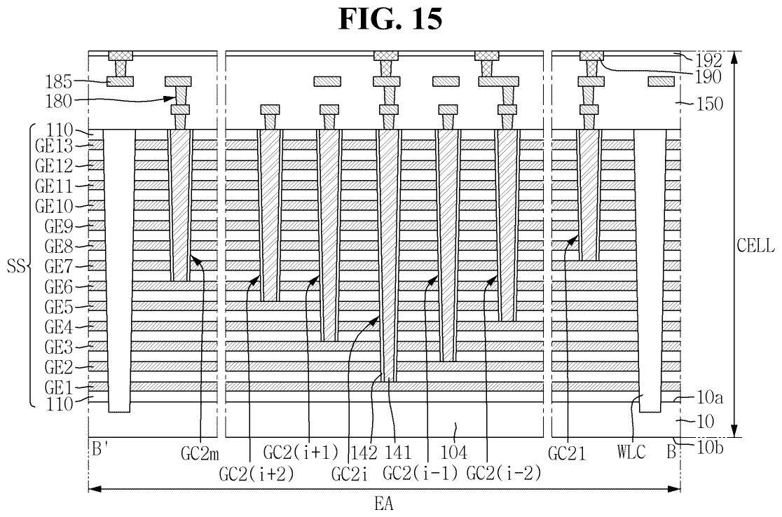

Referring to FIG. 15, a plurality of gate electrodes GE1 to GE13 are formed.

For example, the mold sacrificial film (111 of FIG. 14) exposed by the word line cutting hole (WLCh of FIG. 14) may be selectively removed. Next, gate electrodes GE1 to GE13 that replace the regions from which the mold sacrificial films (111 of FIG. 14) are removed may be formed. Accordingly, a stacked structure SS including the mold insulating film 110 and the gate electrodes GE1 to GE13 may be formed.

Subsequently, a word line cutting pattern WLC that fills the word line cutting hole (WLCh of FIG. 14) may be formed. The stacked structure SS may be cut by the word line cutting pattern WLC. The word line cutting pattern WLC may also be described herein as a word line isolation structure.

Subsequently, a first inter-wiring insulating film 150, a first wiring structure 180, a first bonding insulating film 192, and a first bonding metal 190 are formed.

The first inter-wiring insulating film 150 and the first wiring structure 180 may be formed on the stacked structure SS. The first wiring structure 180 may be electrically connected to the channel structure CH and/or the gate contacts GE21 to GE2m. The first bonding insulating film 192 and the first bonding metal 190 may be formed on the first inter-wiring insulating film 150. The first bonding metal 190 may be electrically connected to the first wiring structure 180.

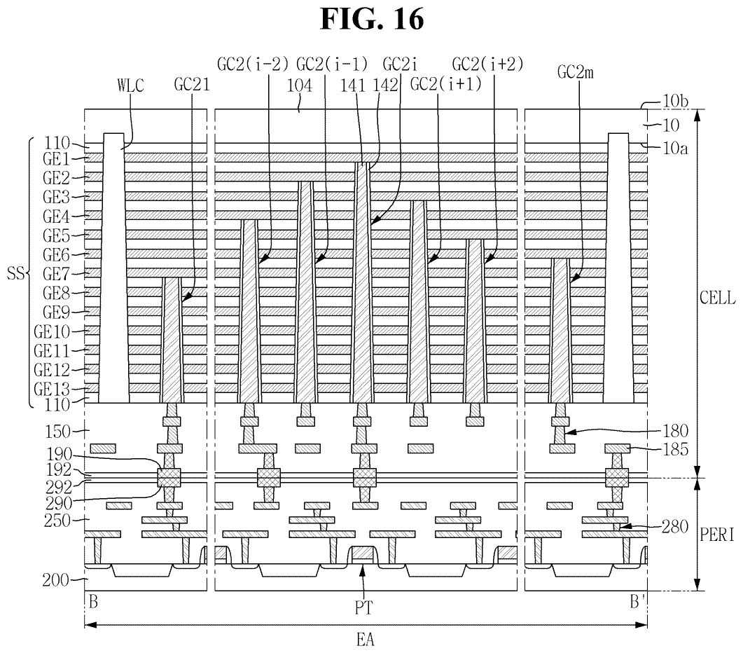

Referring to FIG. 16, the memory cell structure CELL is stacked on the peripheral circuit structure PERI.

The memory cell structure CELL may be stacked such that the first side 10a of the base substrate 10 is opposite to the peripheral circuit structure PERI. For example, the first bonding metal 190 (and/or the first bonding insulating film 192) formed on the uppermost metal layer of the memory cell substrate CELL (on the basis of the direction from the second side 10b to the first side 10a of the base substrate 10), and the second bonding metal 290 (and/or the second bonding insulating film 292) formed on the uppermost metal layer of the peripheral circuit structure PERI (on the basis of the direction from the back side to the front side of the second substrate 200) may be bonded to each other.

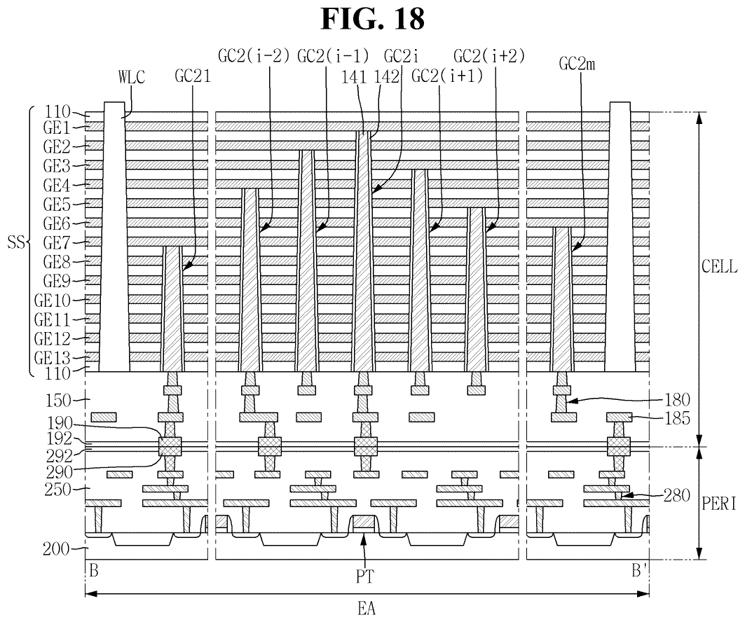

Referring to FIGS. 17 and 18, the base substrate (10 of FIG. 16) is removed. Accordingly, one end (for example, the upper end in the third direction Z) of the channel structure CH may be exposed. One end (e.g., the upper end in the third direction Z) of the word line cutting pattern WLC may be exposed.

Referring to FIGS. 3 and 4, the upper portion of the data storage film 132 is removed.

For example, an etching process may be performed on the data storage film 132 exposed by removing the base substrate (10 of FIG. 16). Accordingly, one end (for example, the upper end in the third direction Z) of the semiconductor film 130 may be exposed.

Next, the first substrate 100 including the conductive substrate 102 and the insulating substrate 104 is formed. For example, the conductive substrate 102 may be electrically connected to one end of the exposed semiconductor film 130 (e.g., the upper end in the third direction Z).

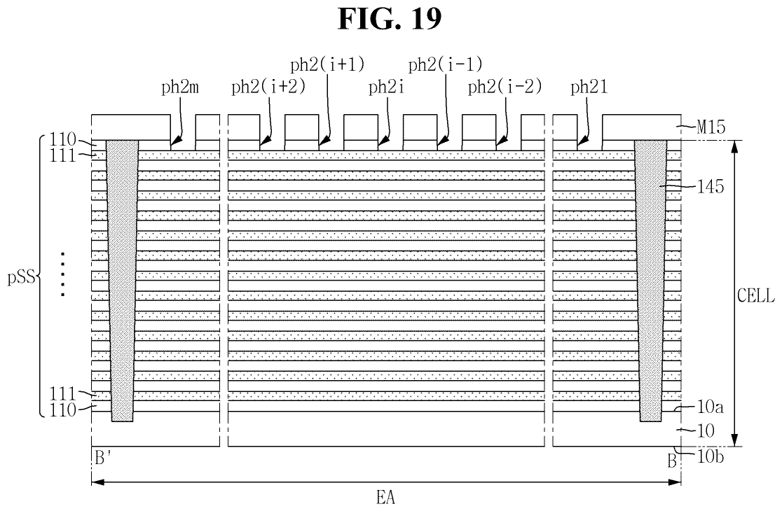

FIGS. 19 to 23 are intermediate step diagrams for explaining a method for fabricating a semiconductor memory device according to some embodiments. For convenience of explanation, repeated parts of contents described above using FIGS. 1 to 18 will be briefly explained or omitted. For reference, FIGS. 19 to 23 are cross-sectional views taken along line B-B′ of FIG. 2, and FIG. 19 is a process performed after FIG. 8. In FIGS. 19 to 23, illustration of the string selection line cutting pattern in FIGS. 2 to 4 is omitted for convenience.

Referring to FIGS. 19 to 23, the preliminary contact holes ph21 to ph2m are formed on the preliminary stack pSS. In some embodiments, the process in which the number of layers of the mold insulating film 110 and the mold sacrificial film 111 etched using a mask pattern is small may be performed first.

Referring to FIG. 19, the mask pattern M15 is formed on the preliminary stack pSS, and the preliminary stack pSS is patterned using the mask pattern M15. The mask pattern M15 is removed.

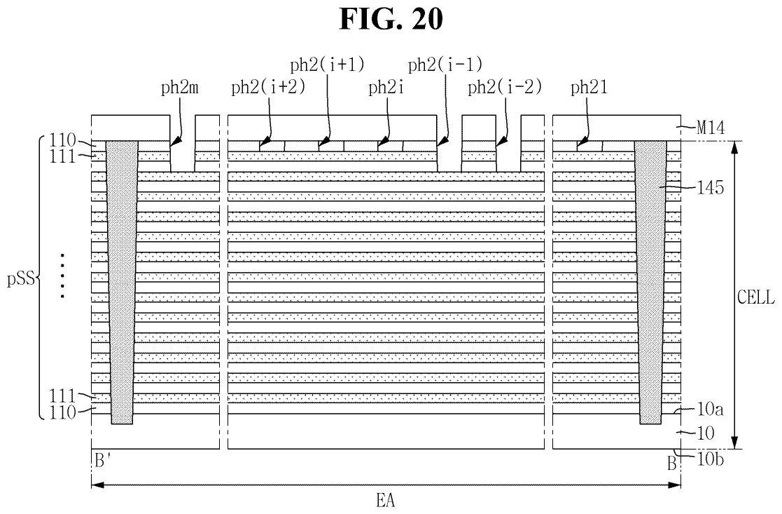

Referring to FIG. 20, the mask pattern M14 is formed on the preliminary stack pSS, and the preliminary stack pSS is patterned using the mask pattern M14. The number of layers of the mold insulating film 110 and the mold sacrificial film 111 that are etched using the mask pattern M14 is larger than the number of layers of the mold insulating film 110 and the mold sacrificial film 111 that are etched using the mask pattern (M15 of FIG. 19). The mask pattern M14 is removed.

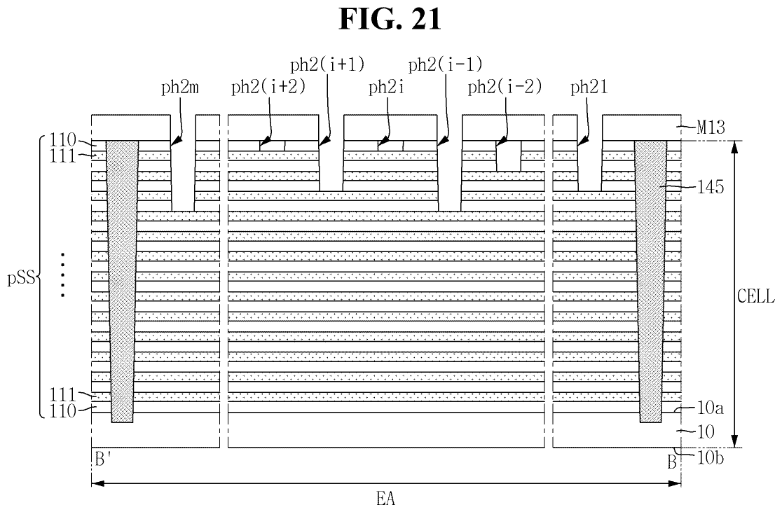

Referring to FIG. 21, a mask pattern M13 is formed on the preliminary stack pSS, and the preliminary stack pSS is patterned using the mask pattern M13. The number of layers of the mold insulating film 110 and the mold sacrificial film 111 that are etched using the mask pattern M13 is larger than the number of layers of the mold insulating film 110 and the mold sacrificial film 111 that are etched using the mask pattern (M14 of FIG. 20). The mask pattern M13 is removed.

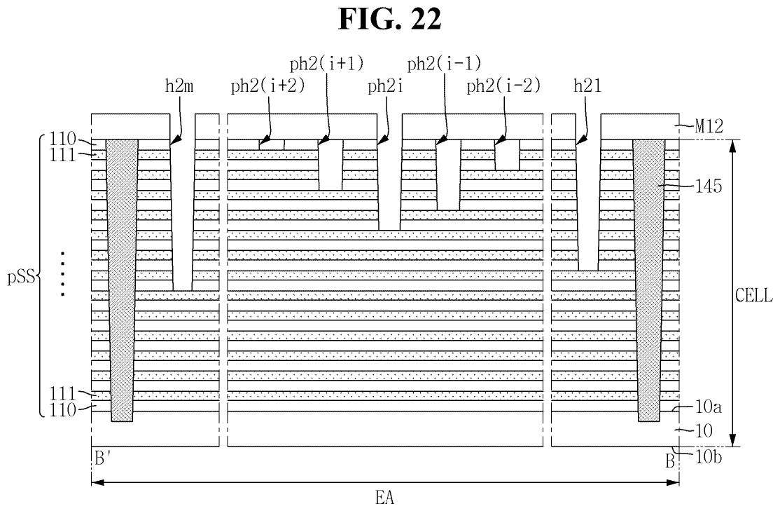

Referring to FIG. 22, the mask pattern M12 is formed on the preliminary stack pSS, and the preliminary stack pSS is patterned using the mask pattern M12. The number of layers of the mold insulating film 110 and the mold sacrificial film 111 that are etched using the mask pattern M12 is larger than the number of layers of the mold insulating film 110 and the mold sacrificial film 111 that are etched using the mask pattern (M13 of FIG. 21). The mask pattern M12 is removed.

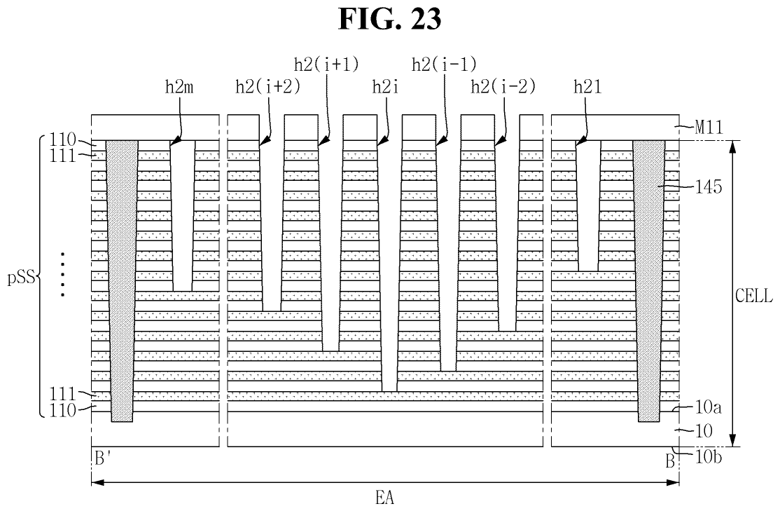

Referring to FIG. 23, a mask pattern M11 is formed on the preliminary stack pSS, and the preliminary stack pSS is patterned using the mask pattern M11. The number of layers of the mold insulating film 110 and the mold sacrificial film 111 that are etched using the mask pattern M11 is larger than the number of layers of the mold insulating film 110 and the mold sacrificial film 111 that are etched using the mask pattern (M12 of FIG. 22). The mask pattern M11 is removed. Accordingly, gate contact holes h21 to h2m are formed.

Next, the fabricating processes described above using FIGS. 14 to 18 may be performed.

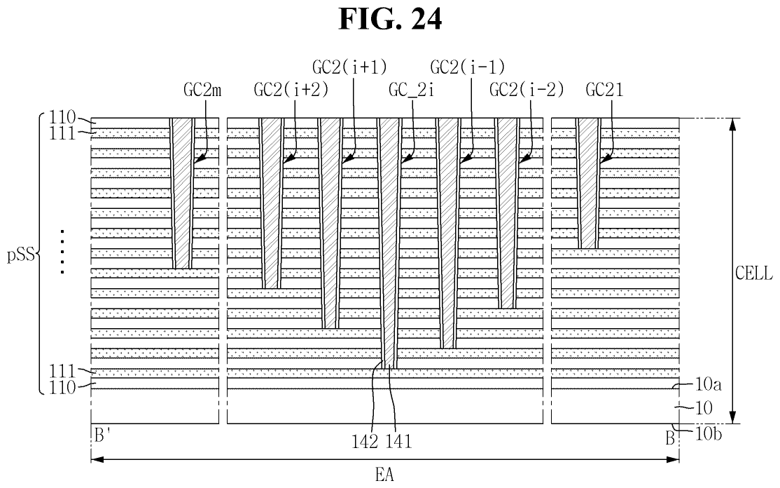

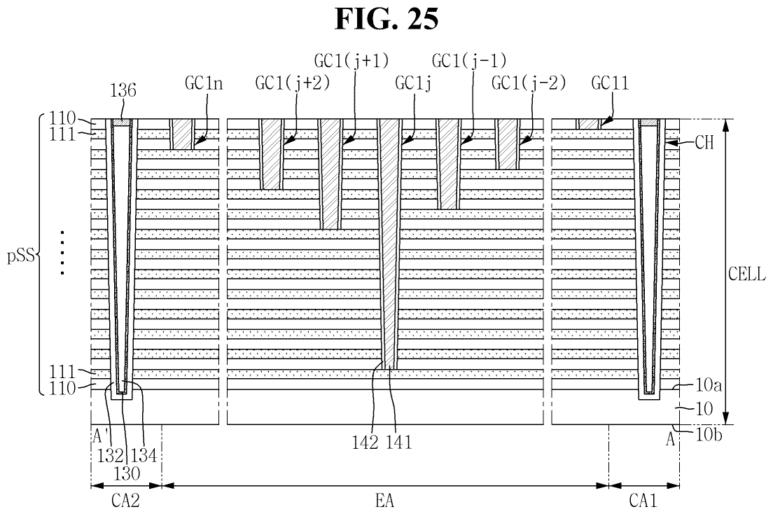

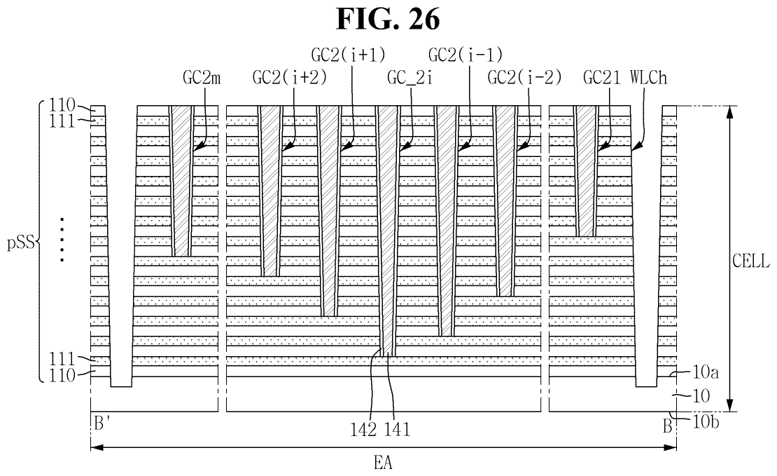

FIGS. 24 to 26 are intermediate step diagrams for explaining a method for fabricating a semiconductor memory device according to some embodiments. For convenience of explanation, repeated parts of contents described above using FIGS. 1 to 23 will be briefly explained or omitted. For reference, FIGS. 24 and 26 are cross-sectional views taken along a line B-B′ of FIG. 2, and FIG. 25 is a cross-sectional view taken along a line A-A′ of FIG. 2. In FIGS. 24 to 26, illustration of the string selection line cutting pattern in FIGS. 2 to 4 is omitted for convenience.

Referring to FIG. 24, the preliminary stack pSS and the gate contacts GC21 to GC2m are formed on the base substrate 10.

The gate contacts GC21 to GC2m may be formed by the fabricating process described above using FIGS. 9 to 14 or the fabricating process described above using FIGS. 19 to 23.

Referring to FIGS. 25 and 26, a channel structure CH and a word line cutting hole WLCh are formed.

The gate contacts GC11 to GC1n may be formed in the process of fabricating the gate contacts GC21 to GC2m of FIG. 24. The channel hole in which the channel structure CH is formed may be formed simultaneously with the word line cutting hole WLCh, or may be formed separately from the word line cutting hole WLCh.

Next, the fabricating process described above using FIGS. 15 to 18 may be performed.

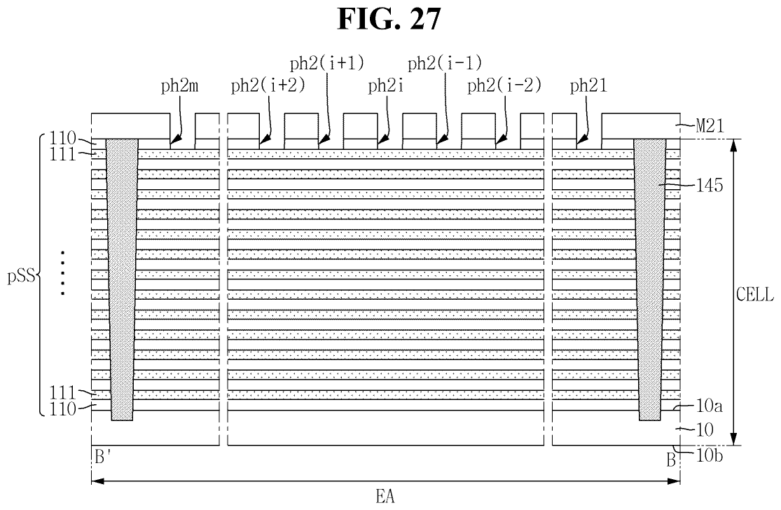

FIGS. 27 to 29 are intermediate step diagrams for explaining a method for fabricating a semiconductor memory device according to some embodiments. For convenience of explanation, repeated parts of contents described above using FIGS. 1 to 26 will be briefly explained or omitted. For reference, FIGS. 27 to 29 are cross-sectional views taken along a line B-B′ of FIG. 2, and FIG. 27 shows the process performed after FIG. 8. In FIGS. 27 to 29, illustration of the string selection line cutting pattern in FIGS. 2 to 4 is omitted for convenience.

Referring to FIGS. 27 to 29, in some embodiments, preliminary contact holes ph21 to ph2m are formed in the preliminary stack pSS through a trimming process.

Referring to FIG. 27, the mask pattern M21 is formed on the preliminary stack pSS, and the preliminary stack pSS is patterned using the mask pattern M21. The preliminary stack pSS exposed by the mask pattern M21 is etched to form the preliminary contact holes ph21 to ph2m.

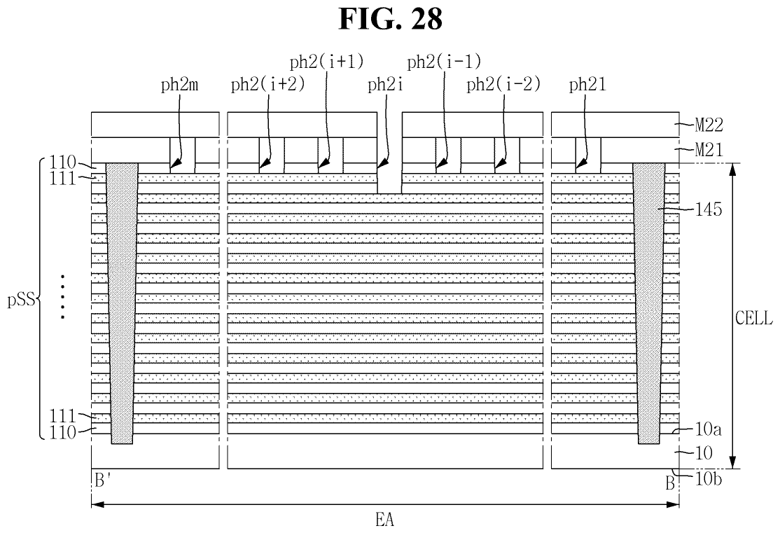

Referring to FIG. 28, the mask pattern M22 is formed on the mask pattern M21, and the preliminary stack pSS is patterned using the mask pattern M22. The preliminary contact hole ph2i may be exposed by the mask patterns M21 and M22. The mold insulating film 110 and the mold sacrificial film 111 exposed by the preliminary contact hole ph2i are etched. For example, each of the mold insulating film 110 and the mold sacrificial film 111 may be etched one layer at a time, but the number of layers of the mold insulating film 110 and the mold sacrificial film 111 to be etched is not limited thereto.

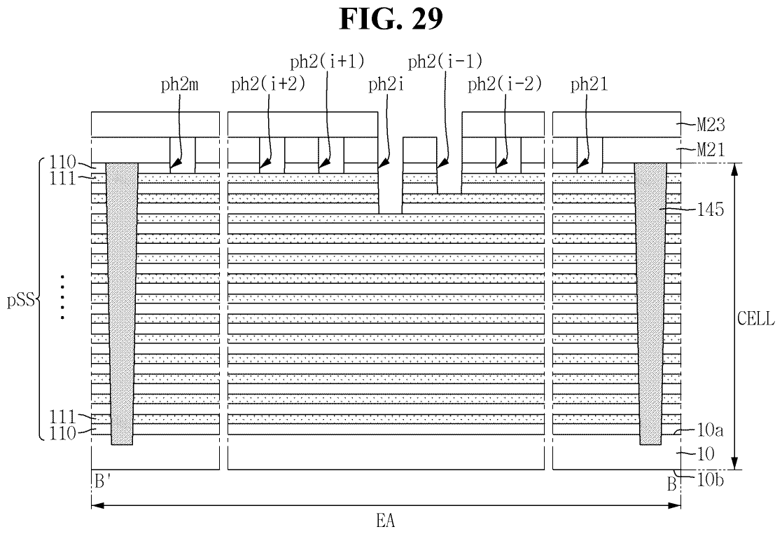

Referring to FIG. 29, a mask pattern M23 is formed through a trimming process of etching a part of the side wall of the mask pattern M22, and the preliminary stack pSS is patterned using the mask pattern M23. The mask patterns M21 and M23 expose preliminary contact holes ph2 (i−1) and ph2i. The mold insulating film 110 and the mold sacrificial film 111 exposed by the preliminary contact holes ph2 (i−1) and ph2i are etched. For example, each of the mold insulating film 110 and the mold sacrificial film 111 may be etched one layer at a time, but the number of layers of the mold insulating film 110 and the mold sacrificial film 111 to be etched is not limited thereto.

Thereafter, the process of trimming the mask pattern M23 to reduce the area of the mask pattern M23, and patterning the preliminary stack pSS by the use of the mask pattern having the reduced area is repeated, thereby forming the contact holes h21 to h2m of FIG. 13.

Next, the fabricating process described above using FIGS. 14 to 18 may be performed.

It should be noted that in the above examples, the formation of the gate contacts specifically for a row of gate contacts in the second direction Y is disclosed. However, the process additionally includes forming an array of gate contacts in both the second direction Y and the first direction X. The examples above would be applied to an array of gate contacts, in order to form gate contacts having a pyramid shape such as discussed previously in connection with some embodiments. Alternatively, in some embodiments, a pyramid shape may not be implemented, and instead topmost surfaces of the plurality of gate contacts may form a dual-planar shape having two planes meeting at an angle, so that a set of longest gate contacts, for example arranged in a row in the first direction X, form an apex of the dual-planer shape. The above process may be applied to an array of gate contacts having this shape and arrangement.

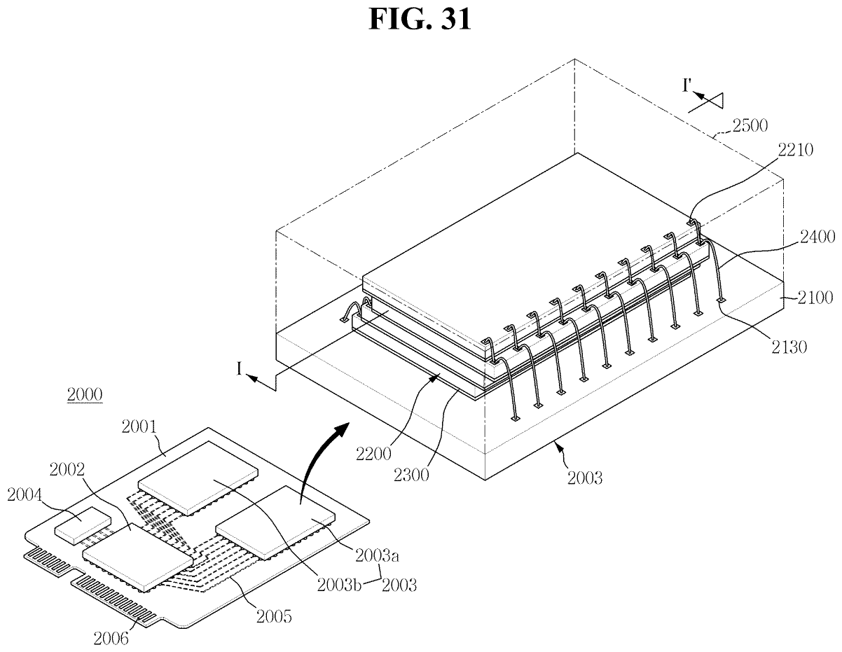

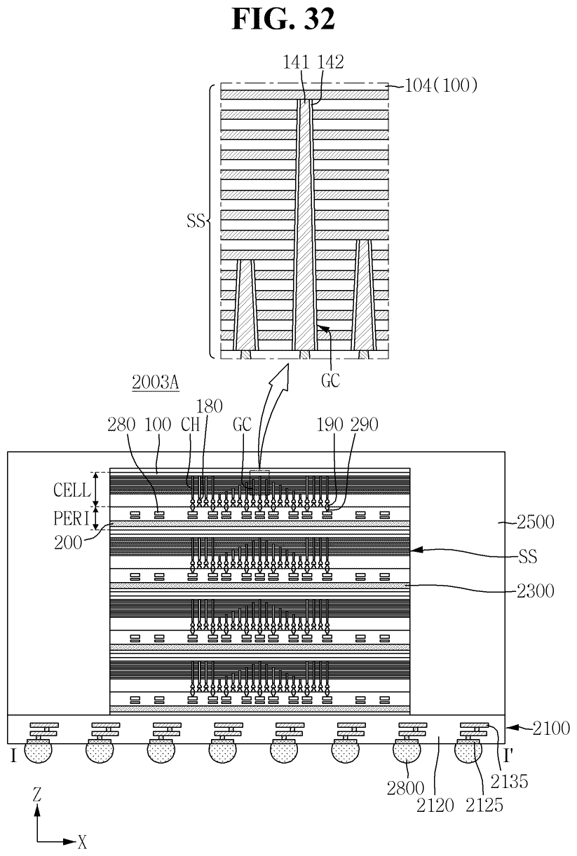

FIG. 30 is an example block diagram for explaining an electronic system according to some embodiments. FIG. 31 is an exemplary perspective view for explaining the electronic system according to some embodiments. FIG. 32 is a schematic cross-sectional view taken along a line I-I′ of FIG. 31. For convenience of explanation, repeated parts of contents described above using FIGS. 1 to 29 will be briefly explained or omitted. The line I-I′ of FIG. 32 is a cross-sectional view taken along the first direction X.

Referring to FIG. 30, an electronic system 1000 according to some embodiments may include a semiconductor memory device 1100, and a controller 1200 electrically connected to the semiconductor memory device 1100. The electronic system 1000 may be a storage device that includes one or multiple semiconductor memory devices 1100, or an electronic device that includes the storage device. For example, the electronic system 1000 may be an SSD device (solid state drive device), a USB (Universal Serial Bus), a computing system, a medical device or a communication device that includes one or multiple semiconductor memory devices 1100.

The semiconductor memory device 1100 may be a non-volatile memory device (e.g., a NAND flash memory device), and may include, for example, at least one of the semiconductor memory devices described above using FIGS. 1 to 6 and/or the semiconductor memory devices fabricated by fabricating process of the semiconductor memory device described above using FIGS. 7 to 29. The semiconductor memory device 1100 may include a first structure 1100F and a second structure 1100S on the first structure 1100F.

The first structure 1100F may be a peripheral circuit structure that includes a decoder circuit 1110, a page buffer 1120, and a logic circuit 1130. The first structure 1100F may correspond to, for example, the peripheral circuit structure PERI described above using FIGS. 1 to 6.

The second structure 1100S may include the common source line CSL, the plurality of bit lines BL, and the plurality of cell strings CSTR. The plurality of bit lines BL may be arranged two-dimensionally in a plane including the first direction X and the second direction Y. For example, the bit lines BL each extend in the second direction Y, and may be spaced apart from each other and arranged along the first direction X. A plurality of cell strings CSTR may be connected in parallel to each bit line BL. The cell strings CSTR may be commonly connected to the common source line CSL. For example, the plurality of cell strings CSTR may be disposed between the bit line BL and the common source line CSL.

Each cell string CSTR may include a ground selection transistor GST connected to the common source line CSL, a string selection transistor SST connected to the bit line BL, and a plurality of memory cell transistors MCT disposed between the ground selection transistor GST and the string selection transistor SST. Each memory cell transistor MCT may include a data storage element. The ground selection transistor GST, the string selection transistor SST, and the memory cell transistors MCT may be connected in series in the third direction Z.

The common source line CSL may be commonly connected to the sources of the ground selection transistors GST. Also, the ground selection line GSL, the plurality of word lines WL, and the string selection line SSL may be disposed between the common source line CSL and the bit line BL. The ground selection line GSL may be used as a gate electrode of the ground selection transistor GST, the word lines WL may be used as the gate electrodes of the memory cell transistors MCT, and the string selection line SSL may be used as the gate electrode of the string selection transistor SST.

In some embodiments, an erase control transistor may be further disposed between the common source line CSL and the ground selection transistor GST. The common source line CSL may be commonly connected to the sources of the erase control transistors. Further, an erase control line may be further disposed between the common source line CSL and the ground selection line GSL. The erase control line may be used as the gate electrode of the erase control transistor. The erase control transistors may perform the erase operation of the memory cell array, using a gate induced drain leakage (GIDL).

The cell strings CSTR may be connected to the decoder circuit 1110 through the plurality of word lines WL, at least one string selection line SSL, and at least one ground selection line GSL. Additionally, the cell strings CSTR may be connected to the page buffer 1120 through the bit line BL. The second structure 1100S may correspond to, for example, the memory cell structure CELL described above using FIGS. 1 to 6. Although not shown, the second structure 1100S may further include various sub-circuits, such as an input/output circuit, a voltage generation circuit that generates various voltages necessary for the operation of the semiconductor memory device 1100, and an error correction circuit that corrects errors of data read from the memory cell array.

The decoder circuit 1110 may select at least one of a plurality of memory cell blocks (for example, BLK of FIG. 2) in response to address, and may select at least one word line WL, at least one string selection line SSL and at least one ground selection line GSL of the selected memory cell block. Further, the decoder circuit 1110 may transfer a voltage for performing a memory operation to the word line WL of the selected memory cell blocks.

The page buffer 1120 may be connected to the memory cell array through the bit line BL. The page buffer 1120 may operate as a writer driver or a sense amplifier. Specifically, when the program operation is performed, the page buffer 1120 may operate as the writer driver to apply a voltage according to the data to be stored in the memory cell array to the bit line BL. On the other hand, when the read operation is performed, the page buffer 1120 may operate as a sense amplifier to sense the data stored in the memory cell array.

The logic circuit 1130 may be connected to the decoder circuit 1110, the input/output circuit, and the voltage generation circuit. The logic circuit 1130 may control the overall operation of the semiconductor memory device 1100. The logic circuit 1130 may generate various internal control signals used within the semiconductor memory device 1100 in response to the control signals. For example, the logic circuit 1130 may adjust the voltage levels provided to the word line WL and the bit line BL when performing the memory operation such as a program operation or an erase operation.

In some embodiments, the common source line CSL and the cell strings CSTR may be electrically connected to the decoder circuit 1110 through first connection wirings 1115 extending from the first structure 1100F to the second structure 1100S.

In some embodiments, the bit lines BL may be electrically connected to the page buffer 1120 through the second connection wirings 1125.

The semiconductor memory device 1100 may communicate with the controller 1200 through an I/O pad 1101 electrically connected to the logic circuit 1130. The I/O pad 1101 may be electrically connected to the logic circuit 1130 through the I/O connection wiring 1135 extending from the inside of the first structure 1100F to the second structure 1100S.

The controller 1200 may include a processor 1210, a NAND controller 1220, and a host interface 1230. In some embodiments, the electronic system 1000 may include a plurality of semiconductor memory devices 1100, and in this case, the controller 1200 may control the plurality of semiconductor memory devices 1100.

The processor 1210 may control the operation of the overall electronic system 1000 including the controller 1200. The processor 1210 may operate according to a predetermined firmware, and may control the NAND controller 1220 to access the semiconductor memory device 1100. The NAND controller 1220 may include a NAND interface 1221 that processes communication with the semiconductor memory device 1100. Control command for controlling the semiconductor memory device 1100, data to be recorded in the memory cell transistors MCT of the semiconductor memory device 1100, data to be read from the memory cell transistors MCT of the semiconductor memory device 1100, and the like may be transmitted through the NAND interface 1221. The host interface 1230 may provide a communication function between the electronic system 1000 and an external host. When the control command is received from the external host through the host interface 1230, the processor 1210 may control the semiconductor memory device 1100 in response to the control command.

Referring to FIGS. 31 and 32, the electronic system according to some embodiments may include a main board 2001, a main controller 2002 mounted on the main board 2001, one or more semiconductor packages 2003, and a DRAM 2004. The semiconductor package 2003 and the DRAM 2004 may be connected to the main controller 2002 by wiring patterns 2005 formed on the main board 2001.

The main board 2001 may include a connector 2006 including a plurality of pins coupled to an external host. In the connector 2006, the number and placement of the plurality of pins may vary depending on the communication interface between the electronic system 2000 and the external host. In some embodiments, the electronic system 2000 may communicate with the external host according to any one of interfaces such as M-Phy for USB (Universal Serial Bus), PCI-Express (Peripheral Component Interconnect Express), SATA (Serial Advanced Technology Attachment), and UFS (Universal Flash Storage). In some embodiments, the electronic system 2000 may operate by power supplied from the external host through the connector 2006. The electronic system 2000 may further include a PMIC (Power Management Integrated Circuit) that distributes the power supplied from the external host to the main controller 2002 and the semiconductor package 2003.

The main controller 2002 may record data in the semiconductor package 2003 or read data from the semiconductor package 2003, and may improve the operating speed of the electronic system 2000.

The DRAM 2004 may be a buffer memory for relieving a speed difference between the semiconductor package 2003, which is a data storage space, and the external host. The DRAM 2004 included in the electronic system 2000 may also operate as a kind of cache memory, and may also provide a space for temporarily storing data in the control operation on the semiconductor package 2003. When the DRAM 2004 is included in the electronic system 2000, the main controller 2002 may further include a DRAM controller for controlling the DRAM 2004, in addition to a NAND controller for controlling the semiconductor package 2003.

The semiconductor package 2003 may include a first semiconductor package 2003a and a second semiconductor package 2003b that are spaced apart from each other. The first semiconductor package 2003a and the second semiconductor package 2003b may each be a semiconductor package that includes a plurality of semiconductor chips 2200. The first semiconductor package 2003a and the second semiconductor package 2003b may each include a package substrate 2100, semiconductor chips 2200 on the package substrate 2100, adhesive layers 2300 disposed on the lower sides of each of the semiconductor chips 2200, a connecting structure 2400 for electrically connecting the semiconductor chips 2200 and the package substrate 2100, and a molding layer 2500 that covers the semiconductor chips 2200 and the connecting structure 2400 on the package substrate 2100.

The package substrate 2100 may be a printed circuit board that includes package upper pads 2130. Each semiconductor chip 2200 may include an I/O pad 2210. The I/O pad 2210 may correspond to the I/O pad 1101 of FIG. 30.

In some embodiments, the connecting structure 2400 may be a bonding wire that electrically connects the I/O pad 2210 and the package upper pads 2130. Therefore, in each of the first semiconductor package 2003a and the second semiconductor package 2003b, the semiconductor chips 2200 may be electrically connected to each other by a bonding wire type, and may be electrically connected to the package upper pads 2130 of the package substrate 2100. In some embodiments, in each of the first semiconductor package 2003a and the second semiconductor package 2003b, the semiconductor chips 2200 may be electrically connected to each other by a connecting structure including a through electrode (Through Silicon Via, TSV) instead of the connecting structure 2400 of the bonding wire type.

In some embodiments, the main controller 2002 and the semiconductor chips 2200 may also be included in a single package. In some embodiments, the main controller 2002 and the semiconductor chips 2200 are mounted on a separate interposer substrate different from the main board 2001, and the main controller 2002 and the semiconductor chips 2200 may also be connected to each other by the wiring formed on the interposer substrate.

In some embodiments, the package substrate 2100 may be a printed circuit board. The package substrate 2100 may include a package substrate body portion 2120, package upper pads 2130 disposed on an upper side of the package substrate body portion 2120, lower pads 2125 disposed on a lower side of the package substrate body portion 2120 or exposed through the lower side, and inner wirings 2135 that electrically connect the package upper pads 2130 and the lower pads 2125 inside the package substrate body portion 2120. The package upper pads 2130 may be electrically connected to the connecting structures 2400. The lower pads 2125 may be connected to the wiring patterns 2005 of the main board 2001 of the electronic system 2000 through conductive connections 2800 as in FIG. 31.

In the electronic system 2000 according to some embodiments, each of semiconductor chips 2200 may include the semiconductor memory device described above using FIGS. 1 to 6. For example, each of the semiconductor chips 2200 may include a memory cell structure CELL and a peripheral circuit structure PERI. As an example, the memory cell structure CELL may include the first substrate 100, the stacked structure SS, the channel structure CH, the gate contacts GC (GC11 to GC1n and GC21 to GC2m), and the first wiring structure 180 described above using FIGS. 1 to 6. The peripheral circuit structure PERI may include a second substrate 200 and a second wiring structure 280. The memory cell structure CELL and the peripheral circuit structure PERI may be bonded to each other through a first bonding metal 190 and a second bonding metal 290.

Although the embodiments of the present disclosure have been described above with reference to the accompanying drawings, the present disclosure is not limited to the above embodiments, and may be fabricated in various different forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

1. A semiconductor memory device comprising:
a substrate;
a stacked structure which includes a plurality of mold insulating films and a plurality of gate electrodes that are alternately stacked on the substrate; and
a plurality of gate contacts that penetrate at least a part of the stacked structure, and are electrically connected to the plurality of gate electrodes,
wherein:
the plurality of gate contacts include first to n-th gate contacts (n is a natural number of 3 or more) arranged in sequence along a first direction,
the first to (j−1)-th gate contacts are respectively electrically connected to gate electrodes closer to the substrate as they are closer to a j-th gate contact (j is a natural number equal to or greater than 2 and less than n), and
the (j+1)-th to n-th gate contacts are respectively electrically connected to a gate electrodes that are further from the substrate, as they are further away from the j-th gate contact.

2. The semiconductor memory device of claim 1, further comprising:
a word line cutting pattern which penetrates the stacked structure, and extends in the first direction to separate the plurality of gate electrodes from adjacent sets of gate electrodes.

3. The semiconductor memory device of claim 1, further comprising:
a word line cutting pattern which penetrates the stacked structure, and extends in a second direction intersecting the first direction to separate the plurality of gate electrodes from adjacent sets of gate electrodes.

4. The semiconductor memory device of claim 3,
wherein the first gate contact or the n-th gate contact is adjacent to the word line cutting pattern.

5. The semiconductor memory device of claim 1, wherein:
the plurality of gate contacts include (n+1)-th to (n+m)-th gate contacts (m is a natural number of 3 or more) arranged in sequence along a second direction intersecting the first direction,
the (n+1)-th to (n+i-1)-th gate contacts are respectively electrically connected to gate electrodes closer to the substrate, as they are closer to the (n+i)-th gate contact (i is a natural number equal to or greater than 2 and less than m), and
the (n+i+1)-th to (n+m)-th gate contacts are respectively electrically connected to gate electrodes further from the substrate, as they are further away from the (n+i)-th gate contact.

6. The semiconductor memory device of claim 1,
wherein the number of the first to (j−1)-th gate contacts is identical to the number of the (j+1)-th to n-th gate contacts.

7. The semiconductor memory device of claim 1,
wherein each of the plurality of gate contacts includes a conductive pattern and an insulating pattern that surrounds a side surface of the conductive pattern.

8. The semiconductor memory device of claim 1, wherein:
the plurality of gate contacts include (n+1)-th to (n+m)-th gate contacts (m is a natural number of 3 or more) that are spaced apart from the first to n-th gate contacts in a second direction and arranged in sequence along the first direction,
the (n+1)-th to (n+i-1)-th gate contacts are respectively electrically connected to gate electrodes closer to the substrate, as they are closer to the (n+i)-th gate contact (i is a natural number equal to or greater than 2 and less than m), and
the (n+i+1)-th to (n+m)-th gate contacts are respectively electrically connected to the gate electrodes further from the substrate, as they are further away from the (n+i)-th gate contact.

9. The semiconductor memory device of claim 1,
wherein the numbers of the plurality of gate electrodes through which each of the plurality of gate contacts in a row of gate contacts penetrates are different from each other.

10. A semiconductor memory device comprising:
a substrate which includes a cell array region and an extension region;
a stacked structure which includes a plurality of mold insulating films and a plurality of gate electrodes that are alternately stacked on the substrate;
a plurality of word line cutting patterns which extend in a first direction and are arranged in a second direction; and
a plurality of gate contacts each extending in a third direction inside the stacked structure, in the extension region,
wherein:
each of the plurality of gate contacts is terminates at a respective one of the plurality of gate electrodes,
the plurality of gate contacts include first to n-th gate contacts (n is a natural number of 3 or more) arranged in sequence along the first direction or the second direction, and
lengths of each of the first to n-th gate contacts in the third direction increase toward a center of the extension region between the word line cutting patterns adjacent to each other in the second direction.

11. The semiconductor memory device of claim 10, wherein:
the cell array region includes a first cell array region and a second cell array region, and
the extension region is interposed between the first cell array region and the second cell array region.

12. The semiconductor memory device of claim 10,
wherein among the plurality of gate contacts, the gate contact having the longest length in the third direction is disposed at the center of the extension region between the word line cutting patterns adjacent to each other in the second direction.

13. The semiconductor memory device of claim 10,
wherein among the plurality of gate contacts, the gate contact having the shortest length in the third direction is closest to the word line cutting pattern or the cell array region.

14. The semiconductor memory device of claim 10, further comprising:
a channel structure penetrating the stacked structure in the cell array region,
wherein:
the channel structure includes a semiconductor film intersecting the plurality of gate electrodes, and a data storage film interposed between the semiconductor film and the plurality of gate electrodes, and
the semiconductor film protrudes beyond the stacked structure and the data storage film and is electrically connected to the substrate.

15. The semiconductor memory device of claim 10, further comprising:
a channel structure penetrating the stacked structure in the cell array region, wherein:
the channel structure includes a first channel structure on the substrate, and a second channel structure connected to the first channel structure and disposed on the first channel structure, and
at a boundary between the first channel structure and the second channel structure, the channel structure has a bent portion, and the plurality of gate contacts have no bent portion.

16. The semiconductor memory device of claim 10, wherein:
each of the plurality of gate contacts includes a conductive pattern, and an insulating pattern which exposes a first end of the conductive pattern, and
the first end of the conductive pattern of each of the plurality of gate contacts is in contact with a respective gate electrode of the plurality of gate electrodes.

17. (canceled)

18. The semiconductor memory device of claim 10, wherein the plurality of word line cutting patterns separate the stacked structure into a plurality of a memory cell blocks, each memory cell block including a set of gate contacts having the arrangement of the first to n-th gate contacts described in claim 10.

19. An electronic system comprising:
a main board;
a semiconductor memory device which includes a peripheral circuit structure and a memory cell structure stacked in sequence on the main board; and
a controller electrically connected to the semiconductor memory device on the main board,
wherein the memory cell structure includes:
a substrate including a cell array region and an extension region,
a stacked structure which includes a plurality of mold insulating films and a plurality of gate electrodes alternately stacked on the substrate,
a word line cutting pattern which penetrates the stacked structure, and extends in a first direction to separate the plurality of gate electrodes,
a channel structure penetrating the stacked structure in the cell array region, and
a plurality of gate contacts which penetrate at least a part of the stacked structure and are electrically connected to the plurality of gate electrodes, in the extension region,
wherein the plurality of gate contacts include first to n-th gate contacts (n is a natural number of 3 or more) arranged in sequence along the first direction or a second direction intersecting the first direction,
the first to (j−1)-th gate contacts are respectively electrically connected to gate electrodes closer to the substrate, as they are closer to a j-th gate contact (j is a natural number equal to or greater than 2 and less than n), and
the (j+1)-th to n-th gate contacts are respectively electrically connected to gate electrodes further from the substrate, as they are further away from the j-th gate contact.

20. The electronic system of claim 19,
wherein the number of the first to (j−1)-th gate contacts is identical to the number of the (j+1)-th to n-th gate contacts.

21. The electronic system of claim 19,
wherein each of the plurality of gate contacts includes a conductive pattern and an insulating pattern.
